(19) United States
(12) Patent Application Publication
(10) Pub. No.: US 2025/0381771 A1
(43) Pub. Date: Dec. 18, 2025

(54) ROLL-BASED CONTACT PRINTING APPARATUS

(71) Applicant: Northeastern University, Boston, MA (US)

(72) Inventors: Ravinder Dahiya, Needham, MA (US); Adamos Christou, Medford, MA (US); Abhishek Dahiya, Medford, MA (US)

(21) Appl. No.: 19/236,521

(22) Filed: Jun. 12, 2025

Related U.S. Application Data
(60) Provisional application No. 63/659,469, filed on Jun. 13, 2024.

(51) Int. Cl. B41F 16/00; B41F 21/00; B41F 33/00

(52) U.S. Cl. CPC B41F 16/006; B41F 16/0026; B41F 16/0073; B41F 16/0093; B41F 21/00; B41F 33/00

(57) ABSTRACT

A system for roll-based printing nanowires on a substrate, including a horizontal stage configured to translate along a first horizontal axis, a donor substrate platform coupled to the horizontal stage, a vertical stage configured to translate along a vertical axis and a receiver substrate platform having a cylindrical surface extending from a first end to a second end along a second horizontal axis, the second horizontal axis perpendicular to the first horizontal axis and wherein the receiver substrate platform is rotatably coupled to the vertical stage.

### CROSS-REFERENCE TO RELATED APPLICATIONS

This application claims the benefit of priority to U.S. Provisional Patent Application No. 63/659,469, filed Jun. 13, 2024, the entirety of which is incorporated by reference herein.

### FIELD OF THE DISCLOSED SUBJECT MATTER

The disclosed subject matter relates to roll-based contact printing. Particularly, the present disclosed subject matter is directed to a roll-based contact printing of nanowires for flexible electronics.

### BACKGROUND OF THE DISCLOSED SUBJECT MATTER

Contact printing shows great potential as a simple, low-cost process for manufacturing printed electronics. The printing method is compatible with a wide range of nanostructure materials enabling a wide new generation of applications. Some implementations utilize a dry process, which aims to minimize contamination—which has significant impact on device performance—while further expanding the list of compatible substrates. One of ordinary skill in the art would appreciate that this process also has its shortcomings.

The planar contact printing showed significant dependence on several parameters of the donor substrate. Studies revealed that the uniformity of the printed NW layer is coupled to the uniformity of the nanostructures synthesized (in this case NWs) on the donor. As a result, any improvement in uniformity requires further optimization of the NW synthesis process which poses a significant challenge. In addition, the size of the printed layer is dictated by the geometrical dimensions of the donor substrate. The geometry is also linked with the applied pressure during printing.

Applied pressure is the printing parameter which can control the density of the printed layers, an important factor for the subsequent device fabrication, which can be a limiting factor for softer substrates where higher pressure could cause damage to the contact surface. Furthermore, a printing system must be capable of applying a wide range of forces with significant resolution to cater to different nanostructure materials as well as donor sizes. Printing at a larger scale poses another challenge while using the planar contact printing system. The conformal contact between donor and receiver substrate is critical for obtaining a uniform printed electronic layer. Planar alignment becomes more challenging as dimensions increase, where factors such as wafer bow can have a significant effect. As such, there is potential for an exponential increase in cost associated with a larger setup that can maintain high levels of accuracy in donor-receiver substrate alignment. Finally, planar alignment can be challenging for standalone flexible substrates (films) since current industry solutions might not be compatible with the high shear forces involved in contact printing.

There thus remains a need for an efficient and economic method and system for roll-based contact printing of nanowires for flexible electronics as described herein.

### SUMMARY OF THE DISCLOSED SUBJECT MATTER

The purpose and advantages of the disclosed subject matter will be set forth in and apparent from the description that follows, as well as will be learned by practice of the disclosed subject matter. Additional advantages of the disclosed subject matter will be realized and attained by the methods and systems particularly pointed out in the written description and claims hereof, as well as from the appended drawings.

To achieve these and other advantages and in accordance with the purpose of the disclosed subject matter, as embodied and broadly described, the disclosed subject matter includes a system for roll-based printing nanowires on a substrate, including a horizontal stage configured to translate along a first horizontal axis, a goniometer stage coupled to the horizontal stage, a donor substrate platform coupled to the goniometer stage, a vertical stage configured to translate along a vertical axis and a receiver substrate platform having a cylindrical surface extending from a first end to a second end along a second horizontal axis, the second horizontal axis perpendicular to the first horizontal axis, the receiver substrate platform rotatably coupled to the vertical stage.

In some embodiments the donor substrate platform comprises a first load cell and a second load cell spaced along the second horizontal axis. In some embodiments the goniometer stage is configured to rotate the donor substrate platform about the first horizontal axis. In some embodiments the goniometer stage comprises an actuator configured to automatedly rotate the goniometer about the first horizontal axis. In some embodiments the system includes at least one controller in communication with the goniometer stage. In some embodiments the system includes a first camera, the first camera oriented along the second horizontal axis and configured to capture at least one image of the donor substrate platform and the receiver substrate platform. In some embodiments the system includes a second camera coupled to the vertical platform and configured to capture at least one image of the donor substrate platform relative to the first horizontal axis. In some embodiments the system includes at least one actuator, the at least one actuator configured to translate at least one of the vertical stage and the horizontal stage. In some embodiments the system includes at least one controller in communication with the at least one actuator configured to control a displacement of at least one of the vertical stage and horizontal stage. In some embodiments the horizontal stage is configured to translate along the second horizontal axis. In some embodiments the system includes a rotating donor substrate stage configured to rotate the donor substrate platform about the vertical axis. In some embodiments the system includes at least one actuator configured to automatedly translate the horizontal stage along the second horizontal axis and rotate the rotating donor substrate stage about the vertical axis. In some embodiments the donor substrate platform comprises a cylindrical loading surface oriented along the second horizontal axis. In some embodiments the donor substrate platform comprises at least one heating element. In some embodiments the donor substrate platform comprises a vacuum sample holder.

The disclosed subject matter also includes a method of roll-based printing of nanowires (NW) on a flexible substrate, the method including loading a donor substrate having a plurality of NW disposed thereon onto a donor substrate platform, loading a receiver substrate on a receiver substrate platform, aligning the donor substrate platform and the receiver substrate platform, wherein the aligning further comprises, contacting the donor substrate platform with the receiver substrate platform, detecting at least one force exerted by the receiver substrate platform on the donor substrate platform and moving at least one of the donor substrate platform and the receiver substrate platform, thereby printing at least a portion of the plurality of NW on the receiver substrate.

In some embodiments aligning the donor substrate platform with the receiver substrate platform comprises rotating the donor substrate platform about the first horizontal axis. In some embodiments moving at least one of the donor substrate platform and the receiver substrate platform comprises translating the donor substrate platform along a first horizontal axis and rotating the receiver substrate platform about a second horizontal axis, simultaneously. In some embodiments moving at least one of the donor substrate platform and the receiver substrate platform comprises at least one of translating the vertical stage along the vertical axis and rotating the donor substrate platform about the first horizontal axis. In some embodiments the method includes monitoring the printing of at least a portion of the plurality of NW on the receiver substrate platform

It is to be understood that both the foregoing general description and the following detailed description are exemplary and are intended to provide further explanation of the disclosed subject matter claimed.

### BRIEF DESCRIPTION OF THE DRAWINGS

A detailed description of various aspects, features, and embodiments of the subject matter described herein is provided with reference to the accompanying drawings, which are briefly described below. The drawings are illustrative and are not necessarily drawn to scale, with some components and features being exaggerated for clarity. The drawings illustrate various aspects and features of the present subject matter and may illustrate one or more embodiment(s) or example(s) of the present subject matter in whole or in part.

FIG. 1 is a schematic representation of a roll-based printing apparatus in accordance with embodiments of the present disclosure, respectively.

FIG. 2 is a schematic representation of roll-based printing in accordance with embodiments of the present disclosure.

FIG. 3 is a schematic representation of a rotating receiver substrate platform and donor substrate platform coupled to a horizontal stage in accordance with embodiments of the present disclosure.

FIG. 4 is a schematic representation of a donor substrate platform coupled to a goniometer stage in accordance with embodiments of the present disclosure.

FIGS. 5A-5B are schematic and photographic representations of a roller receiver substrate platform configured to hold flexible receiver substrate and loading thereof in accordance with embodiments of the present disclosure.

FIG. 6 is a method of printing nanowires from a donor substrate to a receiver substrate in accordance with embodiments of the present disclosure.

FIGS. 7A-7C are block diagrams of a aligning, printing and feedback procedures and subprocesses in accordance with embodiments of the present disclosure.

FIGS. 8A-8B is an exemplary representation of a software platform configured to operate a roll-based printing apparatus in accordance with embodiments of the present disclosure.

FIGS. 9A-9B are schematic representations of goniometer stages in accordance with embodiments of the present disclosure.

FIGS. 10A-10C are schematic representations of loading platforms for donor substrates in accordance with embodiments of the present disclosure.

FIG. 11 is a schematic representation of a roll-based printing apparatus with a camera module and camera image in accordance with embodiments of the present disclosure.

FIG. 12 is a schematic representation of roll-to-roll implementation of roll-based printing using a cylindrical donor substrate in accordance with embodiments of the present disclosure.

FIG. 13 is a schematic representation of a continuously loading apparatus for use in roll-based printing in accordance with embodiments of the present disclosure.

FIG. 14 is a schematic representation of a roll-based printing apparatus for substrate registration alignment in accordance with embodiments of the present disclosure.

FIG. 15 is a photograph of a donor substrate platform with a heating element in accordance with embodiments of the present disclosure.

FIGS. 16A-16E are diagrammatic representations of various printing paradigms in accordance with embodiments of the present disclosure.

FIG. 17 is a diagrammatic side view of a plurality of nanowires contacting receiver substrate and receiver substrate platform forming an effective printing area in accordance with embodiments of the present disclosure.

FIGS. 18A-18B are plots of printing parameters during force variation printing paradigm and SEM images of printed nanowire layers in accordance with embodiments of the present disclosure.

FIGS. 19A-19B are plots of printing parameters during no-rotation printing paradigm and SEM images of printed nanowire layers in accordance with embodiments of the present disclosure.

FIG. 20 are plots of printing parameters and SEM images of printed nanowires during no-sliding printing paradigm according to embodiments of the present disclosure.

FIGS. 21A-21B are plots of printing parameters during velocity ratio printing paradigm and SEM image of printed nanowires according to embodiments of the present disclosure.

FIGS. 22A-22D are plots of electrical characterizations of photodetectors under UV illumination according to embodiments of the present disclosure.

The accompanying drawings, which are incorporated in and constitute part of this specification, are included to illustrate and provide a further understanding of the method and system of the disclosed subject matter. Together with the description, the drawings serve to explain the principles of the disclosed subject matter.

### DETAILED DESCRIPTION OF EXEMPLARY EMBODIMENTS

Reference will now be made in detail to exemplary embodiments of the disclosed subject matter, an example of which is illustrated in the accompanying drawings. The method and corresponding steps of the disclosed subject matter will be described in conjunction with the detailed description of the system.

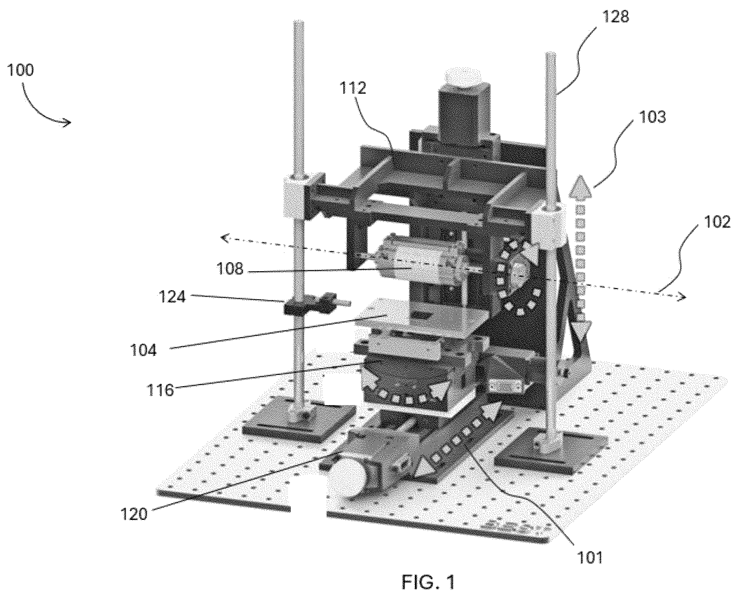

The methods and systems presented herein may be used roll-based printing of nanowires. The disclosed subject matter is particularly suited for precise printing of nanowires on a substrate. For purpose of explanation and illustration, and not limitation, an exemplary embodiment of the system in accordance with the disclosed subject matter is shown in FIG. 1 and is designated generally by reference character 100. Similar reference numerals (differentiated by the leading numeral) may be provided among the various views and Figures presented herein to denote functionally corresponding, but not necessarily identical structures.

Roll-based contact printing could be defined as a process utilizing the normal-shear force mechanism of the conventional (planar) contact printing method while substituting one or both planar substrates holding stages with cylindrical equivalents. Implementing contact printing in a roll-based format can potentially address several of the drawbacks associated with the planar approach described in the previous section. The most prominent advantage is a clearer path towards large scale manufacturing with high throughput, since a roll-based process can increase compatibility with industry standard roll-to-roll (R2R) printing techniques used at other stages of the device fabrication sequence. A roll-based approach reduces the contact area between donor and receiver from a plane to a line. As a result, conformal contact between the substrates can be achieved more easily and accurately since the alignment occurs about one axis instead of two. Additionally, the reduced instantaneous contact area minimizes the risk of damage on the already printed NW arrays which can potentially improve uniformity. The printed area is no longer restricted to the donor size, enabling more control over the dimensions of the printed electronic layers. Lastly, a roll-based approach can be better suited to flexible substrates, catering to the emerging applications for flexible electronics while also supporting compatibility with the well-established roll printing techniques.

The fundamental function of the system is to achieve the combination of normal and shear forces necessary for contact printing, between an arcuate surface, such as a cylindrical surface or section thereof, and a planar surface. In various embodiments, the systems and methods disclosed herein are compatible with flexible receiver substrates which can conform to a cylindrical substrate platform.

Referring to FIG. 1, a schematic representation of a roll-based printing apparatus, referred to herein as printer 100, in accordance with embodiments of the present disclosure is shown. In various embodiments, printer 100 includes horizontal stage 120. Horizontal stage 120 may be coupled to a base member, stationary tabletop or the like. In various embodiments, horizontal stage 120 may be translatably or rotatably coupled to said base member or tabletop. In various embodiments horizontal stage 120 or a portion thereof may be configured to translate along a single axis, such as first horizontal axis 101. In various embodiments, horizontal stage 120 may include a moving platform coupled to a stationary component, such that the moving platform may translate along first horizontal axis 101 between a first end and a second end. In various embodiments, horizontal stage 120 may be configured to move the moving platform past either its first end or second end along first horizontal axis 101. In various embodiments horizontal stage 120 may be configured to translate along first horizontal axis 101 under manual power input by an operator. In various embodiments, horizontal stage 120 may be configured to translate along first horizontal axis 101 automatedly, under power supplied by one or more actuators. For example, and without limitation, horizontal stage 120 may be moved along the first horizontal axis 101 by a linear stage, such as a Physick Instrumente L-406, having a displacement resolution of 0.2 μm. For example, and without limitation, horizontal stage 120 may be actuated by a Physick Instrumente DT-34 rotate stage having an angular displacement resolution of 350 μrad.

In various embodiments, horizontal stage 120 may be configured to translate along more than one axis, such as first horizontal axis 101 and second horizontal axis 102. Second horizontal axis 102 may be perpendicular to horizontal axis 101 and form a horizontal plane. The horizontal plane may be parallel ground level, the base member, or a tabletop on which printer 101 is disposed. In various embodiments, horizontal stage 120 may include a second horizontal stage 120a as shown in reference to FIG. 14. In various embodiments, horizontal stage 120 may be configured to move within the horizontal plane formed by first and second horizontal axes 101, 102, via a combination of linear movements, whether sequentially or simultaneously, thus effecting diagonal motion in the horizontal plane. In various embodiments, printer 100 may include a rotating donor stage 121 configured to rotate at least one of the horizontal stage 120, second horizontal stage 120a, goniometer 116 and donor substrate platform 108 about vertical axis 103. For example and without limitation, rotating donor stage 121 may include a platform or base member on which horizontal stage 120, goniometer 116, and/or donor substrate platform 104 is fixedly positioned on, such that when the rotating donor stage 121 rotates, it imparts at least a portion of said rotation on the donor substrate platform 104. Rotating donor stage 121 may be configured to allow for angular offset or other aligning procedures that could alter printing direction or angle. Rotating stage 121 may be configured to align receiver substrate 107 and donor substrate 106 in a non-uniform orientation which may be constant through printing or change during printing actively. In various embodiments, rotating donor stage 121 may be configured to rotate in response to manual user input or under the power of at least one actuator operatively coupled thereto. In various embodiments, at least one controller may be operatively coupled to the one or more actuators and be configured to control rotating donor stage 121 rotation about the vertical axis 103. In various embodiments, one or more sensors may detect force, visual confirmation, alignment and other parameters which are used to continuously control rotating donor stage 121, for example to align or adjust alignment of receiver substrate platform 108 with donor substrate platform 104.

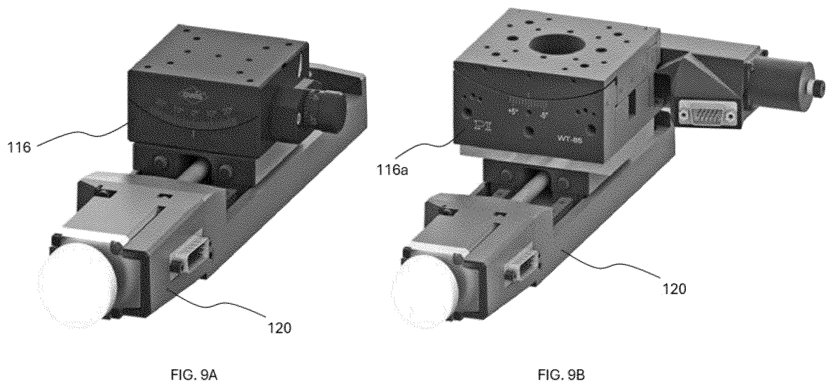

With continued reference to FIG. 1, printer 100 includes goniometer stage 116. Goniometer stage 116 may be coupled to horizontal stage 120 and donor substrate platform 104. For example, and without limitation, goniometer stage 116 may be coupled to the moving portion of horizontal stage 120 such that goniometer stage 116 translate along first horizontal axis 101 and horizontal axis 102, in embodiments. Goniometer stage 116 may be coupled between horizontal stage 120 and donor substrate platform 104, such that donor substrate platform 104 is coupled to goniometer stage 116 directly. Goniometer stage 116 may be configured to rotate donor substrate platform 104 about one or more axes. For example, and without limitation, goniometer stage 116 may be configured to rotate only donor substrate platform 104 relative to horizontal stage 120, such that under the power of the goniometer stage 116, donor substrate platform 104 may be tilted about first horizontal axis 101 or a parallel axis. Goniometer stage 116 may be configured to tilt donor substrate platform 104 to optimize, correct or effect contact between donor substrate platform 104 with one or more receiver substrate platforms, which will be described in detail hereinbelow. In various embodiments, goniometer stage 116 may be rotated about first horizontal axis 101 manually, under power input by the operator or physically moved by the operator. In various embodiments, goniometer stage 116 may be automatedly rotated about first horizontal axis 101 via one or more controllers operatively coupled thereto. In various embodiments, goniometer stage 116 may include one or more actuators within itself, denoted in FIG. 9A-9B as goniometer 116 and goniometer 116a, respectively. For example, and without limitation, goniometer stage 116 may be operatively coupled to or be itself, a Physik Instrumente WY-85 motorized precision goniometer having an angular resolution of 17.5 μrad. In various embodiments, motorized goniometer 116a may automatedly rotate donor substrate platform 104 based on the readings of one or more load cells 105, described below. In various embodiments, the goniometer 116, 116a may continuously rotate about first horizontal axis 101 in response to one or both load cells 105 over the printing process. For example, motorized goniometer 116a may improve alignment variation from 25% to 5%.

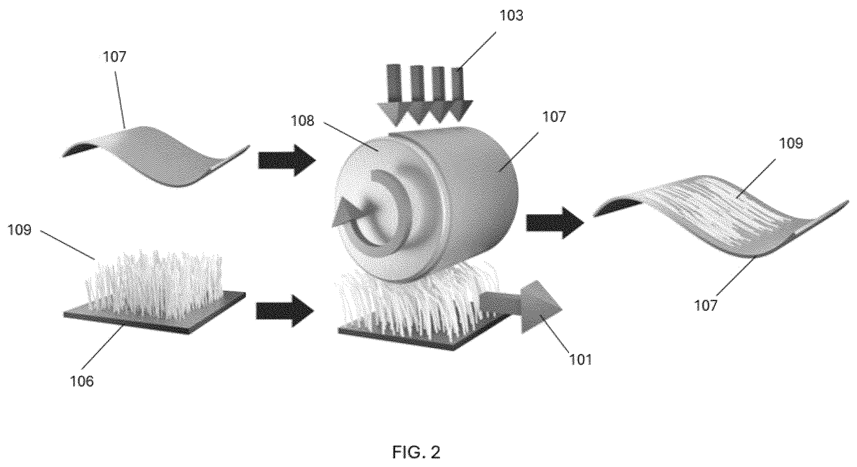

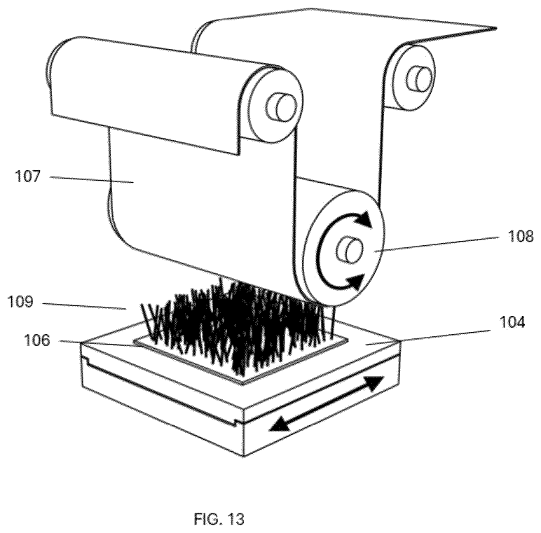

With continued reference to FIG. 1, printer 100 may include donor substrate platform 104. Donor substrate platform 104 may be formed by a planar top surface configured to retain and secure a donor substrate 106, which will be described in reference to FIG. 2. In various embodiments, donor substrate platform 104 may include a generally rectangular planform shape oriented along the first horizontal axis 101 and a second horizontal axis 102. In various embodiments, donor substrate platform 104 may be formed by a cylindrical loading surface, on which donor substrate 106 may be loaded onto, or donor NWs 109 may be formed thereon in a cylindrical fashion, as shown in FIG. 12. The cylindrical donor substrate 106 may be configured with force sensors and/or actuators configured to selective align donor substrate 106 with receiver substrate 107. For example, and without limitation, donor substrate 106 may be configured to tilt in one or more axes, such as vertical axis 103 and second horizontal axis 102. In various embodiments, the cylindrical donor substrate 106 may be configured to rotate about a fixed end, such as in a gimbaling motion, thereby aligning cylindrical donor substrate 106 with the receiver substrate 107. Force sensors in the cylindrical substrate 106 may be configured to provide feedback in order to control directional movement of cylindrical donor substrate 106. Donor substrate platform 104 may be coupled directly to goniometer stage 116 and configured to translate along first horizontal axis 101 therewith. Donor substrate platform 104 may be coupled to horizontal stage 120 and specifically the moving platform such that donor substrate platform 104 may be translated along the first horizontal axis 101 under the power of the horizontal stage 120. In various embodiments, donor substrate platform 104 may include one or more retaining features, such as bosses, clips or the like. In various embodiments, donor substrate platform 104 may include a vacuum sample holder, configured to retain donor substrate 106 via differential pressure, effectively pulling donor substrate 106 to the donor substrate platform 104 by vacuum pressure being supplied by one or more air or other gas supply lines in fluid communication with the donor substrate platform.

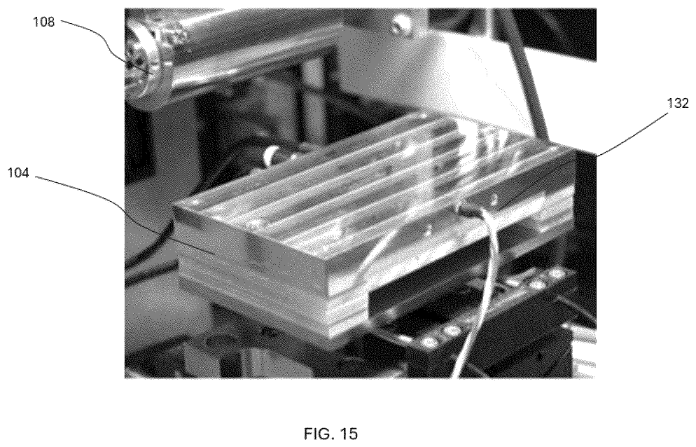

In various embodiments, donor substrate platform may include one or more heating elements 132 as shown in FIG. 15. Heating elements 132 may be disposed within donor substrate platform 104 on the loading surface of the donor substrate platform 104. In various embodiments, heating elements 132 may be disposed on an underside of donor substrate platform 104, for example between donor substrate platform 104 and goniometer 116. Printing techniques, such as the previously reported direct roll printing as described herein, rely on precise temperature control to achieve optimal results. This motivated the design of a heated platform that can be incorporated in printer 100. Heating elements 132 may be customizable, for example, the placement and power requirement of the heating elements 132, the placement of the temperature probe and any thermal insulation. For example and without limitation, heating elements 132 may include a pair of 30 W heating elements and a resistance temperature detector, such as n RTD-PT100, operatively connected to one or more controllers, such as a PID controller for precise temperature control. In various embodiments, donor substrate platform 104 may include thermally insulating material configured to isolate the heated donor substrate platform 104 from the rest of the system to ensure accurate operation of the load cells 105. In various embodiments, donor substrate platform 104 may include precise temperature control in the targeted region of about 50-70° C. with sufficient uniformity on the loading surface. In various embodiments, the temperature near the load cells may be around 30° C. such that the force measurements remain unaffected by the temperature change. The designed arrangement could be beneficial when scaling up roll-based printing techniques, such as direct-roll printing since the temperature increase can be applied locally while a part of the receiver substrate platform 108 is in contact with the heated donor substrate 107.

In various embodiments, the heating elements 132 may be integrated with the vacuum sample holder to create a unified substrate retention and thermal management system. The vacuum sample holder may include thermally conductive pathways that distribute heat from the heating elements 132 across the donor substrate platform 104 while maintaining vacuum integrity through sealed channels and fittings. In some aspects, the vacuum channels may be designed to avoid direct contact with the heating elements 132 to prevent thermal expansion effects that could compromise the vacuum seal. The integrated design may include temperature sensors positioned near the vacuum ports to monitor thermal gradients and ensure that the vacuum system operates within acceptable temperature ranges. In various embodiments, the heating elements 132 may be positioned in zones between vacuum channels, allowing for uniform heat distribution while maintaining the differential pressure needed for substrate retention. This integrated approach may provide both mechanical and thermal control of the donor substrate 106, enabling consistent substrate positioning and temperature conditions throughout the printing process.

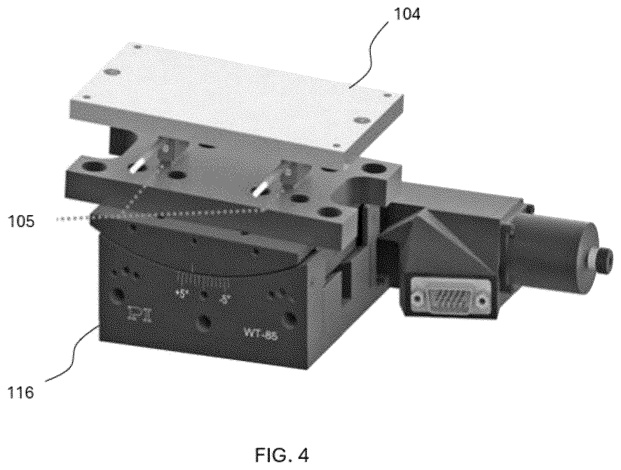

Donor substrate platform 104 may include one or more load cells 105. In various embodiments, donor substrate platform 104 may include two load cells 105. The two load cells 105 may be disposed on an underside of donor substrate platform 104, extending from the underside of the donor substrate platform 104 to a base plate of the donor substrate platform 104 or goniometer stage 116 as shown in FIG. 4. Load cells 105 placed underneath the donor substrate platform 104 may be configured to monitor the applied force exerted on the donor substrate platform 104 from above and allow for closed loop control. The load sensing donor substrate platform 104 may be configured to provide the sensory feedback to one or more controllers, such as closed loop controllers that drive the printing process. Printer 100 is configured to minimize any potential measurement errors to improve the system's accuracy, both in loading conditions and platform alignment.

For example, and without limitation, a pair of Flintec ISA miniature s-beam force transducers may be load cells 105, allowing for a total loading capacity of 40 N and high measurement accuracy of ±0.1%. In various embodiments, the one or more load cells 105 may be spaced along the second horizontal axis 102, thereby configured to monitor the force exerted along said axis and therefore the contact between donor substrate platform 104 and a receive substrate platform oriented along said axis. Based on load cells 105 measurements, goniometer stage 116 may be rotated to effect optimized contact between one or more substrate platforms. The two load cells 105 may be purposefully placed at the two sides of the donor substrate platform 104 to provide a means for monitoring the alignment between the planar and cylindrical platforms—as will be described hereinbelow. For example, when the two platforms are in contact, a mismatch in the force measurements of the two load cells 105 can indicate a non-conformal contact—notifying a user or at least one controller thereof, prompting adjustment.

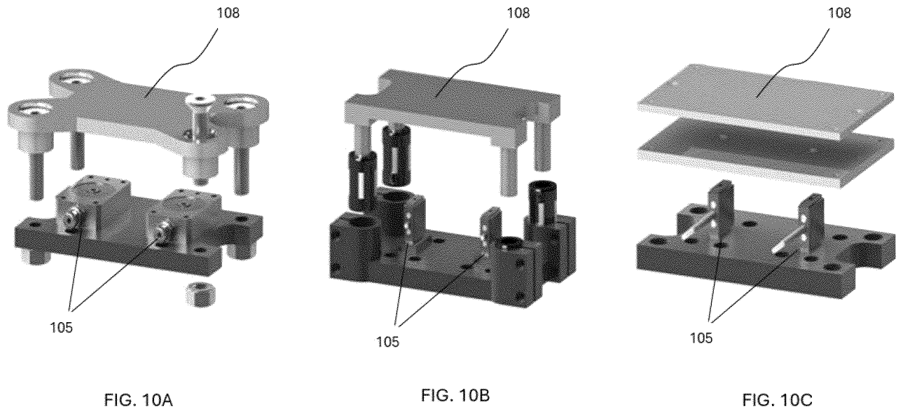

In various embodiments, donor substrate platform 104 may be a floating platform which is not fixed directly to the load cells, as shown in FIG. 10A. The floating platform may be coupled to a based plate by one or more pillars, such as four pillars disposed at each corner of the donor substrate platform to restrict motion to only the vertical axis. The floating platform may reduce error of load cells 105 when forced was applied away from the center line. In other embodiments, donor substrate platform 104 may include linear bearings disposed on or around the support pillars in order to further restrict movement in the horizontal plane as shown in FIG. 10B. In various embodiments, donor substrate platform 104 may include a fixed design, where the top surface is fixed to a base member via one or more intermediary plates. In various embodiments, the fixed donor substrate platform may be affixed to the base member directly by the load cells 105 themselves as shown in FIG. 10C.

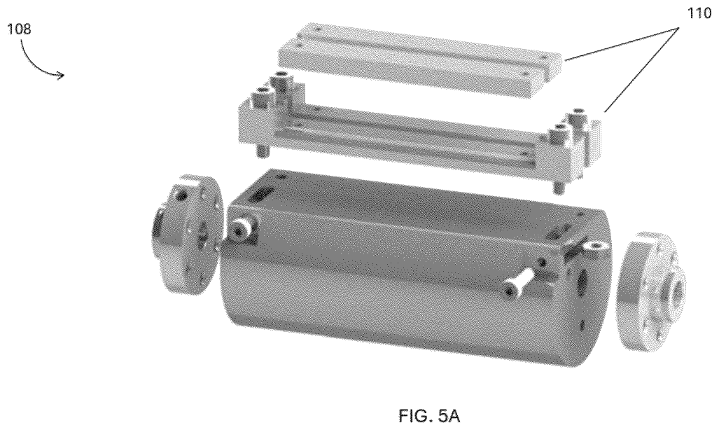

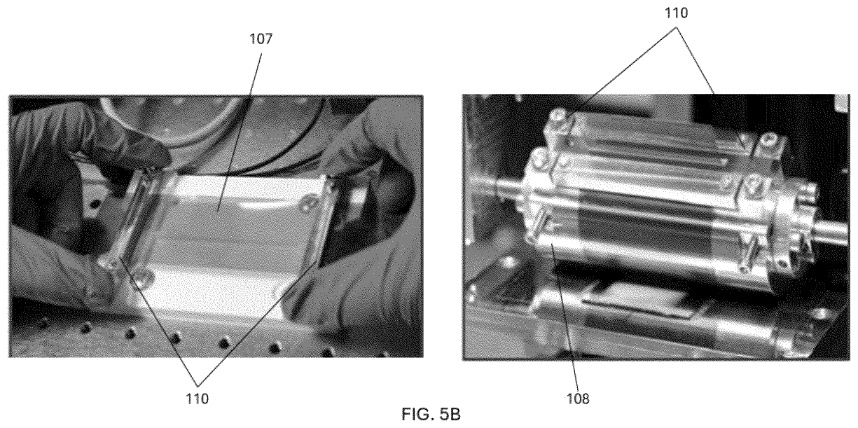

With continued reference to FIG. 1, printer 100 includes a receiver substrate platform 108. Receiver substrate platform 108 may be cylindrical in form, having a first end and a second end having a cylindrical surface extending therebetween along the second horizontal axis 102. In various embodiments, only a portion of the surface is arcuate, for example having a half cylinder face terminating at a planar wall opposite. In various embodiments, receiver substrate platform 108 may have a circular cross section, an arcuate sector cross section, a semicircle cross section, or any other arcuate surface configured to contact the donor substrate platform 104. In various embodiments, receiver substrate platform 108 may be formed, in whole or in part of thermoplastic, metal, composite, or a combination thereof. In various embodiments, the surface of receiver substrate platform 108 may be formed from photopolymer, such as VeroClear™, aluminum or stainless steel. In various embodiments, receiver substrate platform may be additively manufactured, machined, cast or otherwise manufactured from stock, liquid, semi-liquid or solid. In various embodiments, receiver substrate platform may be processed to improve surface roughness, dimensional accuracy, or otherwise. In various embodiments, receiver substrate platform 108 may include one or more retaining features 110, such as clips, clamps, adhesives, or the like, configured to retain receiver substrate 107 on the cylindrical surface of receiver substrate platform 108, as shown in FIGS. 5A-5B. For example, and without limitation, a pair of removable clamps 110 are attached to the flexible receiver substrate 107 while it is in a flat orientation, using a loading base specifically designed to match the circumference of the receiver substrate platform 108, as shown in FIG. 5B. The clamps 110 can then be installed onto the receiver substrate platform 108, wrapping the flexible substrate 107 around it, and a pair of adjustment screws allow for tensioning of the substrate to achieve conformal contact onto the receive substrate platform 108, as shown in FIG. 5B.

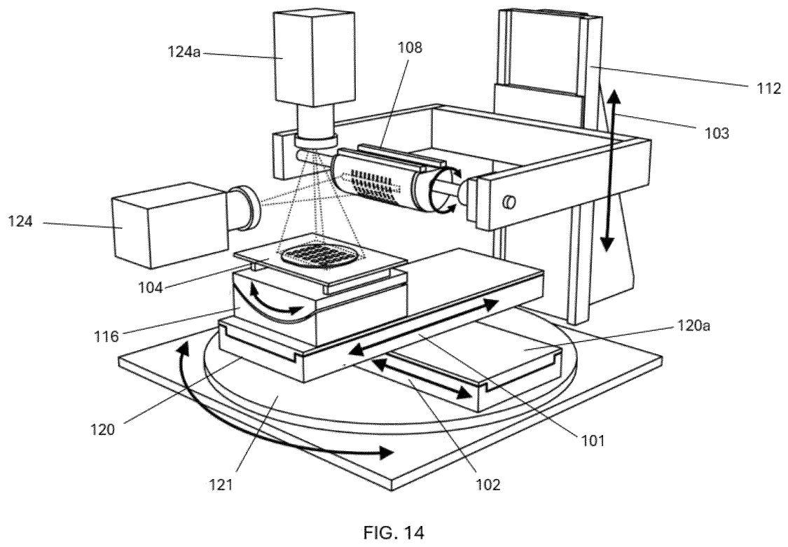

In various embodiments, receiver substrate platform 108 may be configured to continuously load and unload receiver substrate 107. Towards integration in a R2R manufacturing process chain for high performance printed electronics, the receiver substrate platform 108 can be configured to operate with a continuous web printing assembly. For example, and without limitation, receiver substrate platform 108 may be configured to tension and roll receiver substrate 107 about one or more rollers that are continuously loaded and unloaded thereon, as shown in FIG. 13. For example, and without limitation, fresh receiver substrate 107 may be fed from a spool or other receptacle through at least one roller which feeds said receiver substrate 107 onto the receiver substrate platform 108, which performs any print procedures while thereon, and unloads the printed receiver substrate 107 onto at least one second roller for post-processing or other operations, automated or manual. In various embodiments, donor substrate 106 may be configured for more than one printing run, such that any unused NWs are printed on a second run or in a second direction. In various embodiments, the donor substrate 106 may be configured to grow NWs on a flexible substrate, such as by hydrothermal growth, and attached to a belt for feeding into printing.

In various embodiments, the continuous web printing assembly may include tension control mechanisms configured to maintain consistent substrate tension throughout the printing process. The tension control may be achieved through motorized rollers, dancer arms, or load cells that monitor and adjust the tension applied to receiver substrate 107. Proper tension control ensures uniform contact between the receiver substrate 107 and the cylindrical surface of receiver substrate platform 108, which is critical for achieving consistent nanowire transfer and print quality across the entire length of the substrate web.

In various embodiments, the continuous web printing assembly may include web guiding systems configured to maintain lateral alignment of receiver substrate 107 as it moves through the printing system. The web guiding systems may include edge sensors, pneumatic or mechanical edge guides, and steering rollers that automatically correct for any lateral drift of the substrate. This lateral control is particularly important for maintaining registration alignment between donor substrate 106 and receiver substrate 107 during continuous operation.

In various embodiments, the R2R manufacturing process may include pre-treatment and post-treatment stations positioned before and after the roll-based contact printing operation. Pre-treatment stations may include substrate cleaning systems, surface activation treatments, or primer application systems that prepare receiver substrate 107 for optimal nanowire adhesion. Post-treatment stations may include curing systems, protective coating applications, or quality inspection systems that ensure the printed nanowire patterns meet specified performance criteria.

In various embodiments, the continuous web printing assembly may be configured to operate at variable web speeds to accommodate different printing paradigms and substrate materials. The web speed control system may be synchronized with the horizontal stage 120 and receiver substrate platform 108 rotation to maintain optimal differential velocities for each specific printing application. Variable speed capability allows the system to optimize throughput while maintaining print quality for different nanowire materials and substrate combinations.

In various embodiments, the continuous web printing assembly may include web accumulation systems such as festoon accumulators or loop control systems that allow for temporary speed variations during the printing process. These accumulation systems enable the printing operation to proceed at optimal speeds while accommodating any necessary pauses or speed changes required for substrate loading, alignment procedures, or quality control inspections without interrupting the overall web flow.

Receiver substrate platform 108 is configured to rotate about the second horizontal axis 102. Receiver substrate platform 108 may be configured to rotate completely, such that it can freely spin about second horizontal axis 102 or a portion thereof. For example, receiver substrate platform 108 may be configured to rotate less than a full rotation, and return to an initial radial position. In various embodiments, receiver substrate platform 108 may be configured to rotate according to a predetermined angular distance. In various embodiments, receiver substrate platform 108 may be configured to rotate in one or both directions about second horizontal axis 102. In various embodiments, receiver substrate platform 108 includes one or more actuators configured to rotate said receiver substrate platform 108 about the second horizontal axis 102. In various embodiments, the one or more actuators may be operatively coupled to an axle extending along the second horizontal axis 102 and through the axis of the cylindrical receiver substrate platform 108.

In various embodiments, the rotation of receiver substrate platform 108 may be precisely controlled to achieve specific printing paradigms as described herein. The rotational velocity of receiver substrate platform 108 may be independently controlled relative to the horizontal velocity of donor substrate platform 104, enabling the implementation of various velocity ratio printing paradigms. For example, in density-oriented printing paradigms, the receiver substrate platform 108 may rotate at a slower velocity than the horizontal translation of donor substrate platform 104, resulting in a higher concentration of nanowires being transferred to a smaller area on receiver substrate 107. Conversely, in area-oriented printing paradigms, the receiver substrate platform 108 may rotate at a faster velocity, allowing nanowires from a smaller donor area to be distributed across a larger receiver area.

In various embodiments, the rotational control system for receiver substrate platform 108 may include encoders or other position feedback devices to provide precise angular position information to one or more controllers. This feedback enables closed-loop control of the rotational position and velocity, ensuring repeatable and accurate printing results. The rotational control system may be synchronized with the horizontal stage 120 movement to maintain consistent differential velocities throughout the printing process.

In various embodiments, the receiver substrate platform 108 may be configured to operate in a continuous rotation mode for roll-to-roll manufacturing applications, or in a discrete rotation mode for batch processing applications. In continuous rotation mode, the receiver substrate platform 108 may maintain a constant rotational velocity while receiver substrate 107 is continuously fed through the system. In discrete rotation mode, the receiver substrate platform 108 may rotate through predetermined angular increments between printing operations, allowing for precise positioning of multiple printing areas on a single receiver substrate 107.

In various embodiments, the actuators for receiver substrate platform 108 may include servo motors, stepper motors, or other precision rotational actuators capable of providing the torque and positional accuracy required for the printing process. The actuators may be selected based on the size and weight of receiver substrate platform 108, the required rotational speeds, and the precision requirements of the specific printing application. For example, and without limitation, the receiver substrate platform 108 may be actuated by a Physik Instrumente DT-34 rotation stage with an angular displacement resolution of 350 μrad, providing the precision necessary for accurate nanowire transfer.

In various embodiments, at least one controller may be operatively coupled to the one or more actuators and be configured to control receiver substrate platform 108 rotation about the second horizontal axis 102, vertical displacement along vertical axis 103, or a combination thereof. In various embodiments, one or more sensors may detect force, visual confirmation, alignment and other parameters which are used to continuously control receiver substrate platform 108, for example to increase or decrease force applied to donor substrate platform 104 through contact with said receiver substrate platform 108.

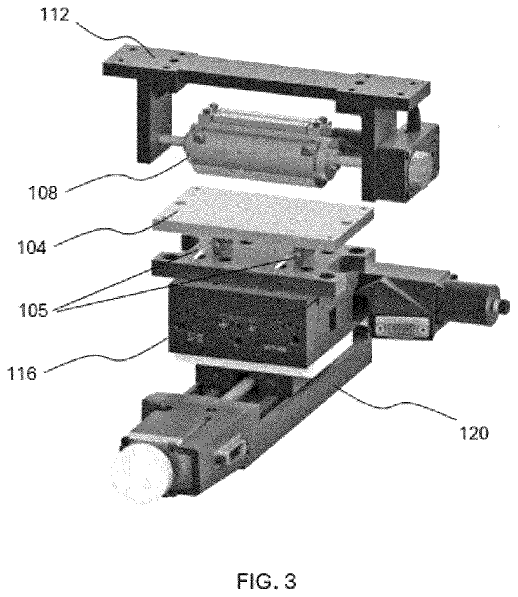

With continued reference to FIG. 1, printer 100 includes a vertical stage 112. Vertical stage 112 is configured to translate along vertical axis 103, which is perpendicular to first horizontal axis 101 and second horizontal axis 102, thus vertical axis 103 is perpendicular to the horizontal plane formed therefrom. Vertical stage 112 may be configured to translate along vertical axis 112 which may be formed perpendicularly to one of a base member, table top or other horizontal surface on which the printer 100 is disposed. Vertical stage 112 is configured to retain receiver substrate platform 108 thereon, and move receiver substrate platform 108 along vertical axis 103 and into contact with donor substrate platform 104. Vertical stage 112 may be formed from a generally vertical member coupled to a base member or table top proximate printer 100 and an one or more arms configured to retain receiver substrate platform 108 therebetween. In various embodiments, as shown in FIG. 3 and in FIGS. 1, 11 and 14, vertical stage 112 may include two arms extending from a vertical member and rotatably coupled to the first and second ends of receiver substrate platform 108. In various embodiments, receiver substrate platform 108 may include an axle oriented along second horizontal axis 102 extending through each of the arms of the vertical stage 112. In various embodiments, vertical stage 112 may include intervening members configured to position receiver substrate platform 108 in a precise orientation relative to the donor substrate platform 104. For example and without limitation, vertical stage 112 may include a forked member including two or more arms, retaining the receiver substrate platform 108 therebetween. In various embodiments, receiver substrate platform 108 may include downward extending arms such that receiver substrate platform 108 hangs below the forked arm portion of vertical stage 112. Vertical stage 112 may include one or more linear stages oriented along the vertical axis 103, such as a Physik Instrumente VT-80 linear stage with a displacement resolution of 0.2 μm.

Vertical stage 112 may include one more guide pillars oriented vertically and parallel to vertical axis 103. Guide pillars 128 may be slidingly coupled to a portion of vertical stage 128, such that vertical stage 128 can slide along said guide pillars 128 as it translate along vertical axis 103. In various embodiments, vertical stage 112 may be coupled to one or more guide pillars 128 via bearings, surround each guide pillar 128 and fixed to the forked arm portion of vertical stage 112. Guide pillars 128 are configured to retain linear motion of the vertical stage 112, and therefore receiver substrate platform 108 to strictly along vertical axis 103, maintaining predetermined or measured alignment with donor substrate platform 104, either during alignment or printing subprocesses. In various embodiments, guide pillars 128 may be disposed on either side of the forked arm portion of vertical stage 112, spaced along the second horizontal axis. Vertical stage 112 is configured to apply force to the donor substrate platform 104 through linear displacement of receiver substrate platform 108 until contact is made therebetween. In various embodiments, vertical stage 112 may translate along vertical axis 103 under manual power input by a user, or via one or more actuators. In various embodiments, at least one controller may be operatively coupled to the one or more actuators and be configured to control vertical stage 112 displacement along vertical axis 103. In various embodiments, one or more sensors may detect force, visual confirmation, alignment and other parameters which are used to continuously control vertical stage 112, for example to increase or decrease force applied to donor substrate platform 104 through contact with receiver substrate platform 108.

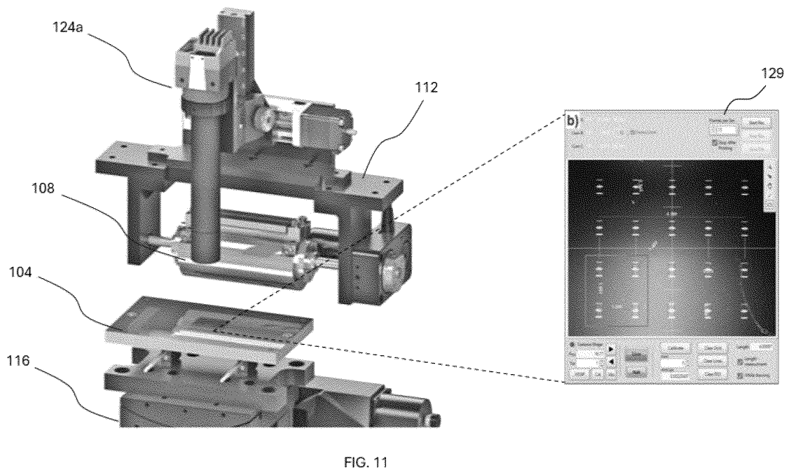

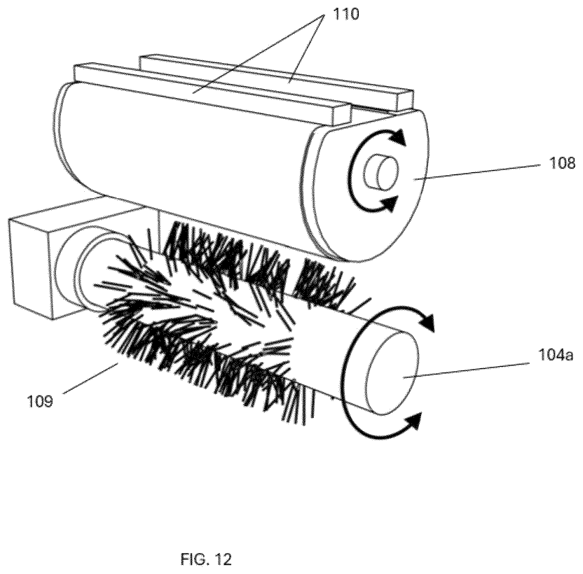

With continued reference to FIG. 1, printer 100 includes one or more cameras 124. One of more cameras 124 are configured to monitor the printing process, either discretely, continuously or a combination thereof. For example and without limitation, a miniature probe camera 124 may be installed oriented along the second horizontal axis 102, focused on a side view of the receiver substrate platform 108. Camera 124 is configured to capture at least one image of the point of contact receiver substrate platform 108 and donor substrate platform 104 during initial positioning of the substrates as well as during the printing process. In various embodiments, a second camera 124, as shown in FIG. 11 and FIG. 14, may be coupled to the vertical stage oriented downward along vertical axis 103, and configured to capture at least one image from above printing. In various embodiments, the cameras 124 are configured to capture at least one image to provide visual feedback to one or more users to facilitate manual adjustments. In various embodiments, camera 124 may be configured to operate on the infrared spectrum in order to capture RI images denoting temperature of one or more components of the system, such as donor substrate platform 104. In various embodiments, cameras 124 may be configured to operate with other metrology components and machine vision algorithms to operate the printer 100 autonomously or semi-autonomously, enabling real-time quality control.

In various embodiments, the cameras 124 may include high-resolution imaging capabilities to detect nanoscale features and defects during the printing process. The cameras 124 may be configured with adjustable focus mechanisms to accommodate different substrate thicknesses and printing configurations. In various embodiments, the cameras 124 may include zoom functionality to provide detailed inspection of specific regions of interest during printing operations.

In various embodiments, the machine vision algorithms may be configured to perform automated pattern recognition to identify alignment markers, substrate boundaries, and printed nanowire patterns. The machine vision system may be configured to automatically detect misalignment conditions and provide corrective feedback to the goniometer stage 116 and other positioning components. In various embodiments, the machine vision algorithms may include defect detection capabilities to identify printing anomalies such as nanowire clumping, incomplete transfer, or substrate damage in real-time.

In various embodiments, the cameras 124 may be operatively coupled to one or more controllers configured to process image data and generate control signals for automated operation. The controllers may be configured to analyze captured images to determine optimal printing parameters, including force application, velocity ratios, and displacement distances. In various embodiments, the image processing system may be configured to generate statistical data regarding printing quality, uniformity, and nanowire density for process optimization and quality assurance purposes.

In various embodiments, the infrared imaging capabilities may be configured to monitor thermal gradients across the donor substrate platform 104 and receiver substrate platform 108 during heated printing operations. The thermal imaging may be used to ensure uniform temperature distribution and prevent thermal damage to sensitive nanowire structures. In various embodiments, the thermal monitoring system may be integrated with heating element 132 control systems to provide closed-loop temperature regulation during printing processes. Printing techniques often rely on registration alignment, where a specific part of the donor substrate 106 must be printed onto a specific part of the receiver substrate 107. In various embodiments, of printer 100, the substrates may be observed prior to printing to make the necessary corrections for registration alignment. In various embodiments, at least one camera 124a may be incorporated which allows for observing the donor substrate 106 while it is mounted on the donor substrate platform 104 as shown in FIG. 11. The camera 124a may be installed on the vertical stage 112 and makes use of the existing vertical stage 112 for focus adjustment. The camera 124a is mounted on a linear stage which allows for scanning the donor substrate 106 along the second horizontal axis 102 while the horizontal stage 120 allows scanning along the first horizontal axis 101.

A camera feed 129 can be seen within the software such that features on the donor substrate 106 can be observed, such as selectively printed patterns or nanoribbon (NR) arrays. Additionally, using machine vision, at least one dimension and/or at least one distance can be detected and/or measured, based on which printing location parameters can be set. Using this camera module 124a, and with the addition of a camera module for observing the receiver substrate 107, such as camera 124, complete registration alignment from donor to receiver could be achieved.

In various embodiments, printer 100 may be configured to operate autonomously, increasing the throughput capabilities for industrial manufacturing. Using a combination of cameras and precision stages substrate registration alignment can be enabled. Specifically, the inclusion a pair of fixed cameras 124, 124a at known offset positions can be used to observe patterns on both the donor substrates 106 and receiver substrates 107. Using the precision stages, horizontal stage 120 and vertical stage 112, and with the addition of a second horizontal stage 120a and rotating donor stage 121, the donor substrate 106 and receiver substrates 107 can be positioned so that their respective patterns align during printing, as shown in FIG. 14, for example. Furthermore, the use of additional metrology equipment, such as additional cameras, infrared (IR) and temperature sensors, and in combination with machine vision processes, real-time quality control capabilities can be also enabled.

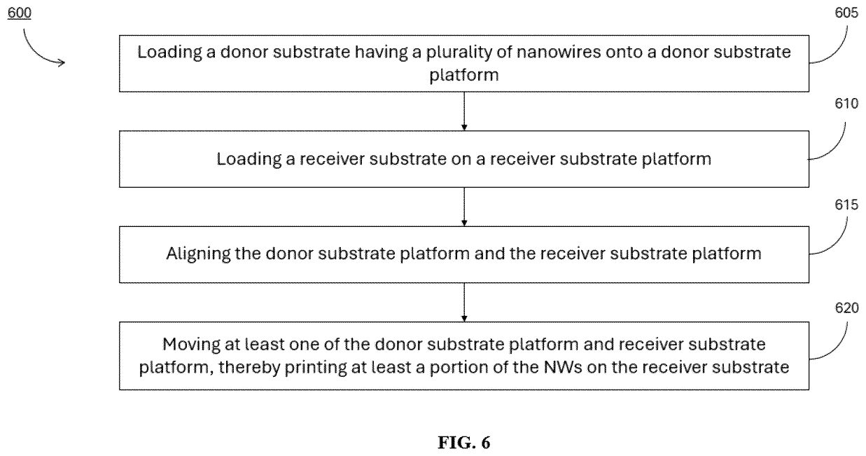

Referring now to FIG. 6, a method for roll-based printing of nanowires (NW) on a flexible substrate in accordance with embodiments of the present disclosure. Method 600 includes, at step 605, loading a donor substrate 106 on donor substrate platform 104. Donor substrate 106 may be secured to donor substrate platform 104 as described herein. In various embodiments, nanowires 109 may be grown, manufactured or deposited on donor substrate 106 as described herein.

With continued reference to FIG. 6, method 600 includes, at step 610, loading a receiver substrate 107 on receiver substrate platform 108. Receiver substrate 107 may be a flexible substrate wrapped over a cylindrical surface of receiver substrate platform 108. In various embodiments, loading the receiver substrate may include securing receiver substrate 107 to receiver substrate platform 108 via one or more clamps 110, as shown in FIG. 5B.

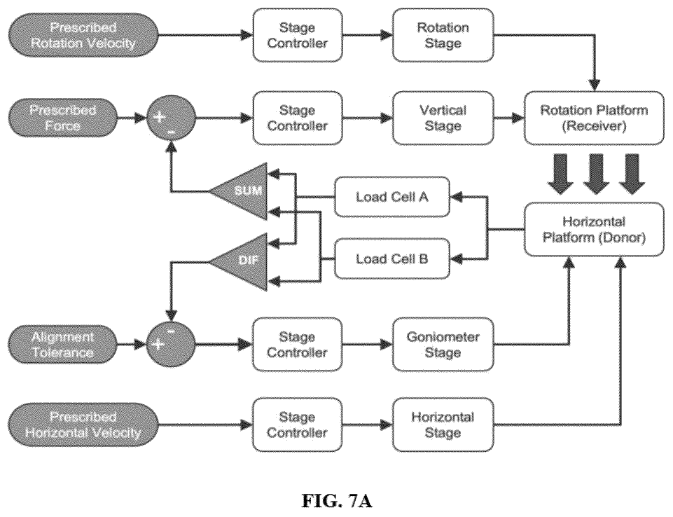

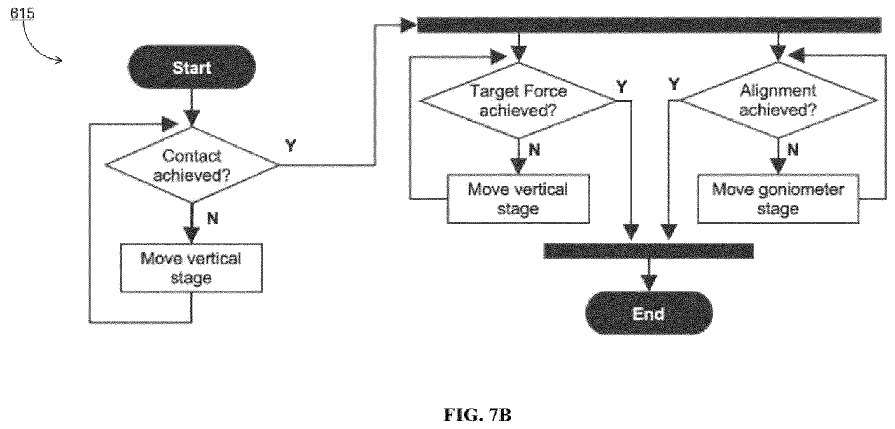

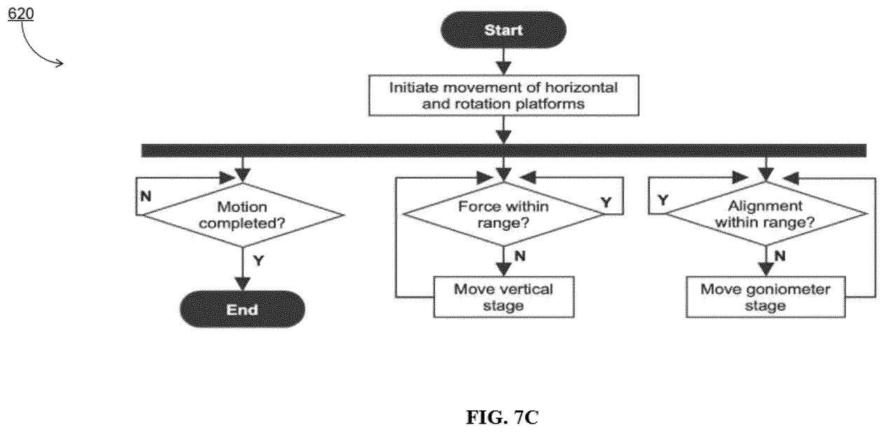

With continued reference to FIG. 6, method 600 includes, at step 615, aligning the donor substrate platform 104 and receiver substrate platform 108. The printing procedure is divided into two main sub-procedures the initial alignment (FIG. 7B) and the printing process (FIG. 7C). Both procedures rely on a set of printing parameters set by the user which include the target force and associated tolerance, the alignment tolerance, the velocities of the two substrate platforms and the target displacement. Aligning may include a plurality of manual or automated sub-steps. During the initial alignment procedure as shown in FIG. 7B, the receiver substrate platform 108 is lowered via vertical stage 112 until contact is achieved with the donor substrate platform 104. In various embodiments, the automated approach sequence ensures that no excess force is applied between the substrates during the initial contact. Subsequently, an alignment controller is enabled, and goniometer stage 116 is adjusted to maintain the difference between the force measurements within the pre-set threshold as measured between load cells 105. Simultaneously, the target force controller is enabled and adjusts vertical stage 112 to reach the desired loading condition. The initial alignment procedure is completed once both the applied force and alignment are stabilized within the pre-set tolerances. In various embodiments, printer 100 may be configured to achieve both targets within a tolerance of 0.02 N.

Any step of method 600 may include a feedback loop system to monitor and maintain the desired printing parameters as shown in FIG. 7A. In various embodiments, two separate proportional controllers may be implemented and operate simultaneously. The first controller may be configured to monitor the sum of force measurements from the load cells 105 and operates vertical stage 112 to achieve the desired loading condition. The second controller may be configured to monitor the difference between the two force measurements between load cells 105 and adjusts the goniometer stage 116 to minimize the discrepancy and maintain optimal contact between the substrates. In various embodiments, the initial alignment procedure 615 may include pausing the vertical movement of vertical stage 112 platform to allow a user to manually adjust the goniometer 116 angular position about the first horizontal axis 101. Once alignment was achieved, the loading was increased, and the process was repeated until the target force was reached as measured by the load cells 105. In various embodiments, the rotation of goniometer 116 may be adjusted automatedly via one or more actuators in response to load cell 105 force measurements.

With continued reference to FIG. 6, method 600 includes, at step 620, moving at least one of the donor substrate platform 104 and receiver substrate platform 108, thereby printing at least a portion of the NWs on the receiver substrate 107. Once the initial alignment procedure is completed, the printing process can be initiated. The first step of sub-procedure 620 may be to simultaneously initiate the motion of the horizontal stage 120 and therefore donor substrate platform 104, and rotation of the receiver substrate platform 108 based on the desired velocities or printing paradigms as described herein.

Step 620 may include moving at least one of the donor substrate platform 104 and the receiver substrate platform 108, such as translating the donor substrate platform 104 along a first horizontal axis 101 and rotating the receiver substrate platform 108 about a second horizontal axis 102, simultaneously, in discrete steps or a combination thereof. In various embodiments, printing may include translating the donor substrate platform 104 along a second horizontal axis 102 or in a horizontal plane formed by horizontal axes 101, 102, for example diagonally. In various embodiments, printing may include rotating donor substrate platform 104 about first horizontal axis 101 while simultaneously moving donor substrate platform 104 within the horizontal plane. In various embodiments, step 620 may include translating receiver substrate platform 108 along vertical axis 103 while simultaneously rotating receiver substrate platform 108. In various embodiments, step 620 may include performing any of the described motions in discrete steps or simultaneously and continuously, thereby continually adjusting displacement, applied force, and relative velocity.

During the printing process, one or both controllers operate in a similar manner as during the initial alignment procedure, continuously adjusting to maintain the target force and alignment as close as possible to the pre-set values. The printing process is completed once the predefined displacement of the donor substrate platform 104 along first horizontal axis 101 or receiver substrate platform 108 rotation about second horizontal axis 102 is achieved. In various embodiments, the final step is to separate the donor substrate platform 104 and receiver substrate platform 108 and move them back to their initial positions for unloading. In various embodiments, printer 100 may be configured to maintain the applied force within 10% of the target while also maintaining a misalignment within 5%.

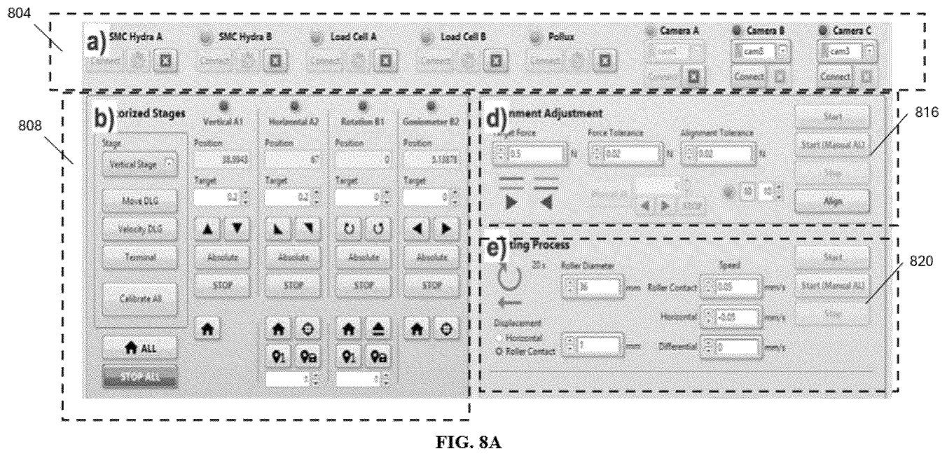

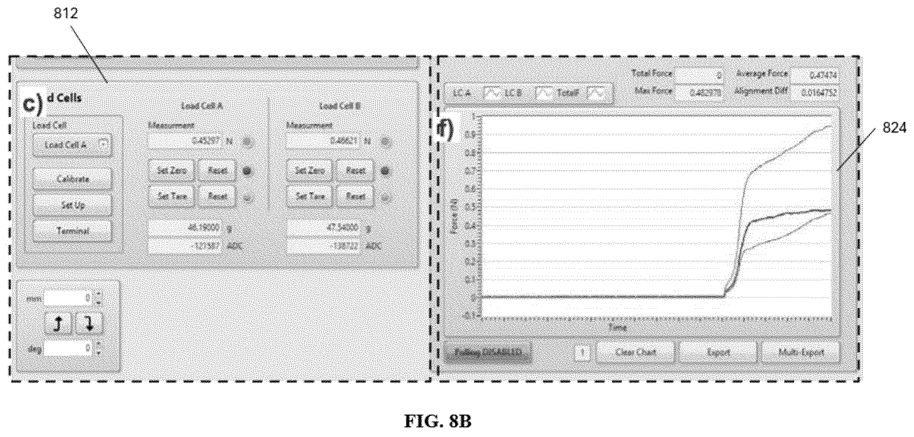

Referring to FIGS. 8A and 8B, software platform 800 may be configured to operate one or more functions of printer 100 and method 600 as described herein. In various embodiments software platform 800 may be deployed in a programming environment, such as National Instruments Lab VIEW graphical programming environment. The software 800 may be configured to interface with one or more actuators as described herein, for example through one or more controllers, such as Physik Instrumente SMC Hydra controllers. In various embodiments, software 800 may be configured to interface with one or more load cells 105, for example via the Flintec LDU digitizing units. In various embodiments, software 800 may be configured to: a) connect with the hardware and enable manual control of each module as shown in reference to reference numeral 804; b) calibrate all components to the required initial states (reference positions of stages, taring of load cells) as shown by reference numeral 808, c) enable setting of the printing parameters as shown by reference numeral 812, d) perform the automated printing procedure based on the selected parameters and as shown by reference numeral 816, and e) export the printing data as shown by reference numeral 820. In various embodiments, software 800 may include a real-time plot of applied forces to each of the load cells 105, as shown by reference numeral 824.

In addition to the main printing procedure 600, the software may include complementary features aiming to improve the overall operation. In various embodiments, excess force protection may be implemented at every stage of the system's operation. Excess force protection may prevent accidental damage to one or more components of printer 100, which could be caused by manual error or during the implementation of new software features. In various embodiments, visualization of printing direction may be implemented to prevent user error while setting the various printing parameters. Given that printer 100 can perform various paradigms of roll-based contact printing (described above and further below), the software 800 may be configured to allow the user to confirm which printing paradigm is selected before executing it, thus avoiding accidental damage to donor and receiver substrates. Software 800 may also incorporate real time monitoring and recording of the printing data, similar to 824. Monitoring is essential to spot any irregularities during the printing process. Automatic recording of both the printing data and parameters facilitates the comparison of various samples at the later stage without wasting time during the printing experiments. In various embodiments, manual overrides may be implemented for both the initial alignment 615 and printing procedures 620. Specifically, this feature allows the user to bypass the alignment controller and perform a manual platform alignment in cases where alternate substrate morphology is used, such as materials that are relatively thicker or softer than donor substrate 106 and receiver substrate 107.

In various embodiments, printer 100 or embodiments thereof may be employed for a plurality of printing procedures or paradigms. The developed roll-based contact printing system printer 100 with independently moving substrate platforms allows for various printing parameters to be adjusted. By selecting specific parameter values, several printing paradigms can be achieved which are described herein. The printing parameters which differentiate and define these paradigms may include horizontal velocity: the velocity of the horizontal stage 120 and therefore donor substrate platform 104, rotation velocity: the velocity of the receiver substrate platform 108 at the point of contact (not the angular velocity); differential velocity: the vector difference of the horizontal and rotation velocities, considering their respective directions, horizontal displacement: the length distance that the donor substrate platform 104 moves during printing, rotational displacement: the length distance covered along the receiver substrate 107 (at the point of contact) during printing, donor/receiver area: the total area of the donor substrate 106 and receiver substrate 107 which is in contact at some point during printing and applied force: the normal force maintained between the two substrates during printing.

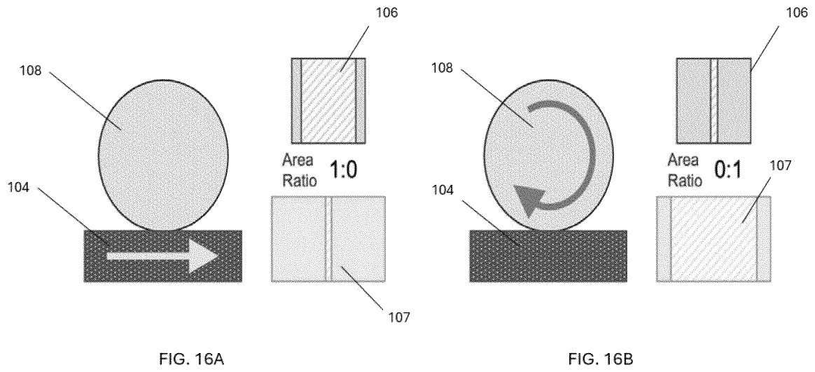

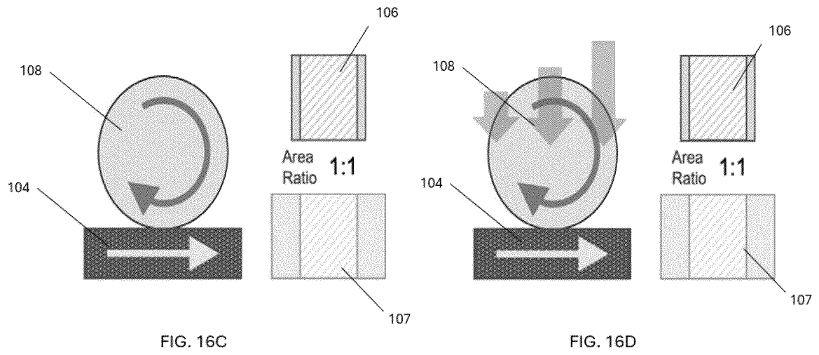

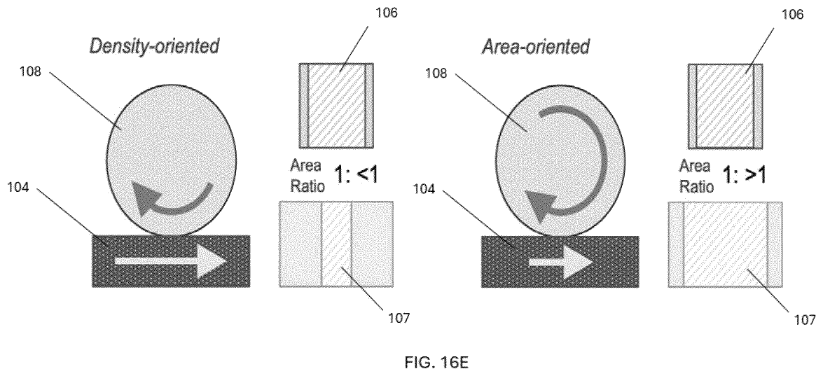

Referring to FIG. 16A, a no rotation regime is represented by a side view of donor substrate platform 104 and receiver substate platform 108 and planform views of the contact area of donor substrate platform 104 and receiver substrate platform 108 during the no rotation printing paradigm. For the ‘no rotation’ paradigm, the receiver substate platform 108 remains stationary while only donor substrate platform 104 moves. This results in the minimum possible receiver area. It allows for a large donor area to be printed on a very small area on the receiver. The differential velocity is equal to the horizontal velocity in said no-rotation paradigm.

Referring to FIG. 16B, a no sliding regime is represented by a side view of donor substrate platform 104 and receiver substate platform 108 and planform views of the contact area of donor substrate platform 104 and receiver substrate platform 108 during the no sliding printing paradigm. For the ‘no sliding’ paradigm, the donor substrate platform 104 remains stationary while only the receiver substate platform 108 moves. This results in the minimum possible donor area. It allows for a very small donor area to be printed on a large area on the receiver. The differential velocity is equal to the rotation velocity.

Referring to FIG. 16C, a conventional contact printing regime is represented by a side view of donor substrate platform 104 and receiver substate platform 108 and planform views of the contact area of donor substrate platform 104 and receiver substrate platform 108 during the conventional contact printing paradigm. For the conventional contact printing, the horizontal and rotation velocities are equal and opposite, resulting in a twice as large differential velocity. Since the two substrate velocities are equal, the resulting area ratio is 1:1, with an area of the donor substrate 106 printing on to an equal area on the receiver substrate 107. This paradigm is the closest to the printing paradigm of planar contact printing where the printed area is equal to the donor size. The sliding speed of planar contact printing is analogous to the differential velocity. Equally increasing or decreasing the horizontal and rotation velocities changes the differential velocity without altering the area ratio.

Referring to FIG. 16D, a force variation printing paradigm is represented by a side view of donor substrate platform 104 and receiver substrate platform 108 and planform views of the contact area of donor substrate platform 104 and receiver substrate platform 108 during the force variation printing paradigm. The force variation paradigm relies of varying the applied force of receiver substrate platform 108 on donor substrate platform 104 and can be done alongside each of the above paradigms. It is the equivalent of the pressure variation for planar contact printing, however, the planar-to-roll configuration alters the contact area and associated pressure.

Referring to FIG. 16E, a velocity variation printing paradigm is represented by a side view of donor substrate platform 104 and receiver substate platform 108 and planform views of the contact area of donor substrate platform 104 and receiver substrate platform 108 during the velocity variation printing paradigm is shown. For this paradigm, the horizontal and rotation velocities are opposite but not equal, and their ratio controls the area ratio. In the case where the horizontal velocity is larger than the rotation velocity, printing is density-focused with the donor substrate 106 area printing on a smaller area on the receiver substrate 107. In cases where the horizontal velocity is lesser than the rotation velocity, printing is area focused with the donor area printing on a larger area on the receiver. The no rotation and no sliding paradigms could be considered as the two extreme cases of the velocity ratio paradigm and all three do not have an equivalent paradigm for the planar contact printing approach. These paradigms are unique to roll-based contact printing and showcase the potential of the roll-based approach.

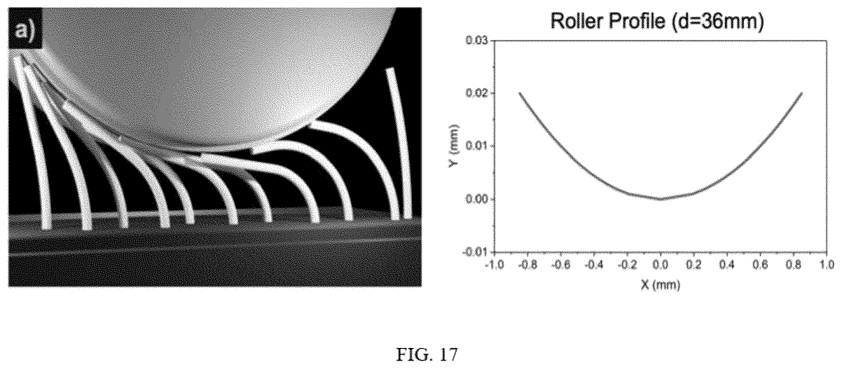

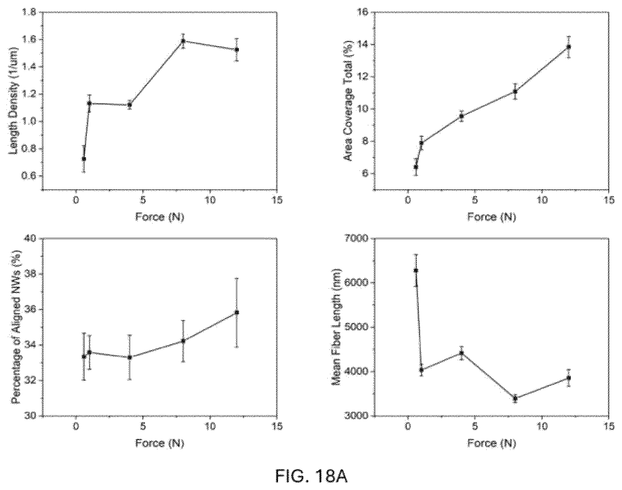

Theory suggests that the interface between the planar and cylindrical platforms is a single line and therefore, has infinitesimally small area. In practice, the instantaneous contact area is significantly larger and possibly relies on parameters such as the diameter of the roller platform, the length of the nanowires (NWs) on the donor, the applied force, and the material of the receiver substrate (FIG. 17). For example, when considering the profile of a 36 mm diameter roller, the size used in the designed system, a donor of 20 μm long NWs could result in a maximum contact width of 17 mm (FIG. 17). Embodiments of printer 100 capable of the no rotation and no sliding paradigms can be used to determine the effective contact width i.e., the minimum contact area.

Following the development of the roll-based contact printing system, a series of printing studies were conducted, aiming to demonstrate the operation of the system. Through these studies the various design elements are evaluated by assessing the printing process performance. The assessment is done in comparison with the planar contact printing system to determine a) the performance of the roll-based approach in equivalent printing paradigms and b) the potential of the printing paradigms unique to the roll-based system. Specifically, the studies carried out include the no rotation and no sliding paradigms, velocity ratio variation and applied force variation.

For the studies discussed in this section, ZnO NWs 109 were used as the printed nanostructure material. The ZnO NWs were synthesized using a bottom-up VPT method, according to embodiments. After printing, SEM images of the printed samples may be analyzed with an open-source image analysis software to extract figures of merit which characterize the printing performance.

The force variation study aims to evaluate the printing performance at different loading conditions to determine the optimal setting for the roll-based contact printing system. The conventional contact printing paradigm was chosen allowing meaningful comparison with the planar contact printing system. As such, the horizontal and rotation velocities were set to 0.05 mm/s (opposite directions), resulting in a differential velocity of 0.1 mm/s. Displacement was set to 8 mm. Tests were carried out at different loading conditions ranging from 0.6 N, close to the system's minimum operating conditions, up to 12 N. Given the significantly reduced contact area for the roll-based approach, the corresponding pressure values for the tested force range are higher than the pressure values used for the planar contact printing system. By considering an estimated contact area of 25 mm² the tested pressure values range from 24 up to 480 kPa.

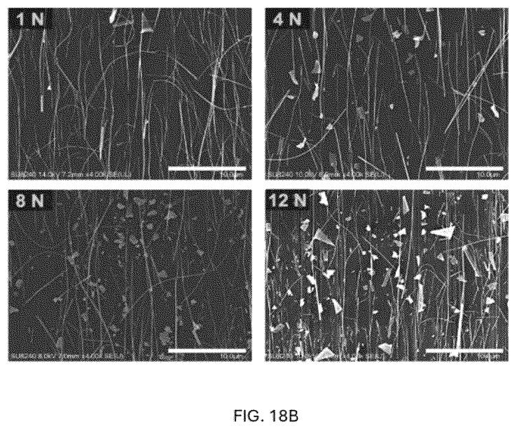

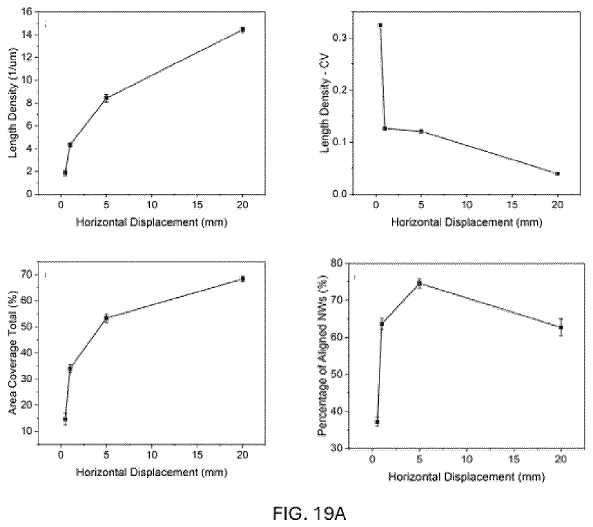

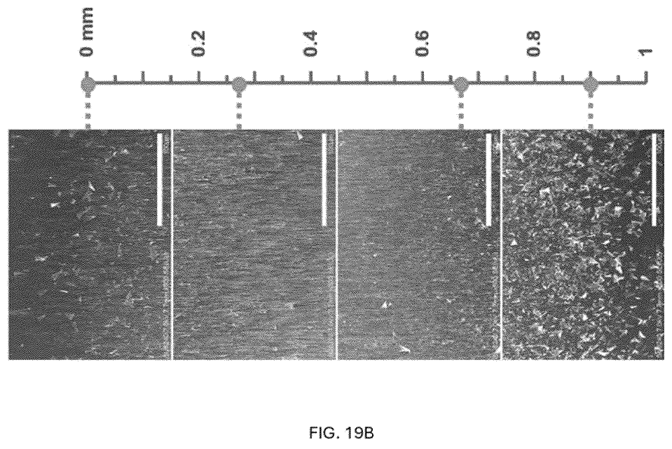

Upon inspecting the SEM images, for all but the lower loading conditions, the printed layers have large concentrations of flakes/particles alongside the printed NWs (FIG. 18B). Such nanostructures are usually present closer to the roots of the NWs on the donor substrate and the SEM results suggest that higher forces significantly increase the transfer of such nanostructures. In addition, an increase in applied force appears to be increasing the presence of smaller NWs, probably by enabling the printing of shorter NWs as well as by breaking longer NWs into smaller pieces. The observation is supported by the plot of the mean fiber length which shows a decrease in length with increasing force (FIG. 18A, lower right hand plot). Damaging of the substrate surface is also observed at higher forces. The increase in applied force does result in a slight increase in NW density and area coverage while alignment remains unchanged (FIG. 18A, upper lefthand plot), in line with the results of the equivalent planar contact printing studies. By considering all the above observations, the optimal loading settings for the roll-based contact printing system are closer to the lower operating values, to avoid large concentrations of flakes/particles which can affect the device performance. Through additional testing a force of 0.8 N was chosen as an optimal setting for the subsequent studies.

The no rotation printing paradigm enables printing of large donor areas on a very small area on the receiver substrate, with the potential of achieving high density printed NW layers. The aim of this study is to test this theory and determine if a control over NW density can be achieved with this paradigm while maintaining the high directional alignment. For these experiments the horizontal velocity was set to 0.1 mm/s to match the differential velocity used in other studies. The applied force was set to 0.8 N following optimization. While the receiver platform remained stationary, the horizontal donor platform was set to move by different length displacements, specifically, 0.5, 1, 5, and 20 mm.

After analyzing SEM images of the printed samples, the initial hypothesis is confirmed since the density of the printed NW layers increases significantly with increasing the horizontal displacement (FIG. 19A, upper lefthand plot). For the smallest displacement of 0.5 mm, the observed length density is around 2 NW/pm, closely matching the maximum density values achieved during the planar contact printing studies. Area coverage is also similar at around 15%. When the horizontal displacement is increased to 1 mm, the observed density increases to around 4 NW/pm, while a displacement of 5 mm results in a further increase to over 8 NW/pm. The latter NW density closely matches the state-of-the-art figures achieved with planar contact printing. Importantly, those state-of-the-art numbers were achieved with a lubricant-assisted method and in some cases using surface functionalization. With the horizontal displacement increased to 20 mm, the observed density reaches over 14 NW/pm which surpasses the current state-of-the-art values of any contact printing approach. The area coverage follows the same trend, reaching a maximum value of around 70%, a 5× increase compared to planar contact printing (FIG. 19A, lower lefthand plot). Significantly, the uniformity of the printed NW layers is also improved when increasing the horizontal displacement. By studying the density coefficient of variation plot (FIG. 19A, upper lefthand plot), lower values are obtained at higher horizontal displacements, meaning that the density values at different locations on the sample are more closely matched. Furthermore, the NW alignment plot illustrates an increase of the percentage of aligned NWs across the sample (FIG. 19A, lower righthand plot).

A closer inspection of the obtained SEM images reveals an interesting phenomenon. While the center region of the printed sample constitutes of highly uniform NW arrays, a large concentration of nano-membranes can be found along the edge of the printed area (FIG. 19B). This becomes more evident for the samples where higher horizontal displacement was applied. This observation suggests that an interaction is taking place during printing, between the printed NWs and those still on the donor substrate. The interaction could be characterized as a “combing” process, where the larger nano-membranes are pushed to the edge of the sample while the printed NWs are better oriented along the printing direction, evident by the improvement in alignment. Importantly, this interaction does not seem to damage the quality of the printed NWs. Although not confirmed at this point, the observed phenomenon is enabling the printing of more uniform NW layers.

The experiments implementing the no rotation paradigm, allow for some deductions to be made regarding the minimum contact area achievable with the developed system. The SEM images reveal a total printing width of just over 1 mm (FIG. 19B). This does not vary significantly with the change of horizontal displacement. The no sliding paradigm experiments can further validate this observation.

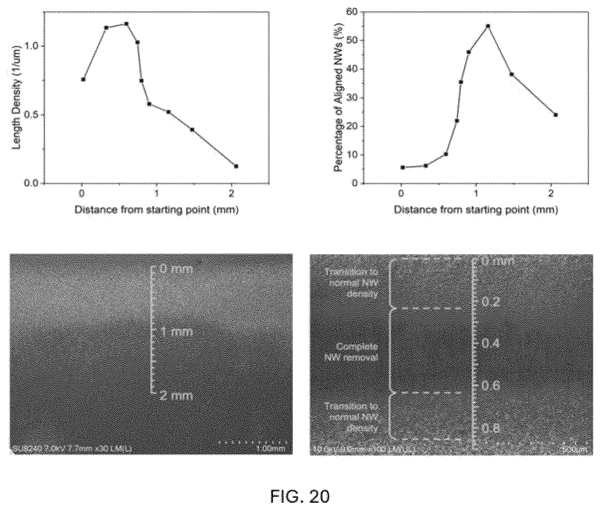

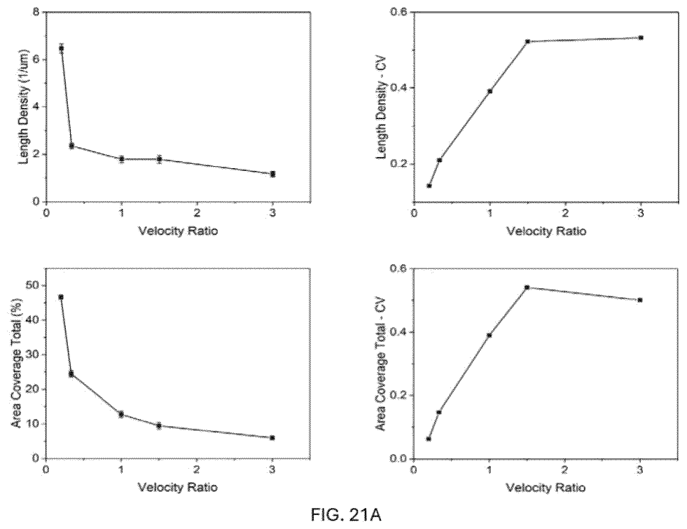

The no sliding printing paradigm achieves the inverse of the previously studied no rotation paradigm, namely printing a very small donor area onto a large area on the receiver substrate. This study aims to experimentally determine the “printing capacity” of the donor substrate i.e., the maximum printed area that can be obtained from a given donor area while maintaining sufficient printing performance. For these experiments, the rotation velocity was set to 0.1 mm/s to match the differential velocity used in other studies while the horizontal platform remained stationary. Like the previous studies, the applied force was set to 0.8 N. The receiver substrate platform was rotated to achieve a contact displacement of 20 mm. The SEM analysis revealed that the printing performance degrades very early into the process. Specifically, by examining the length density plot, the density drops below the initial value after 0.8 mm and by the 2 mm point is very close to 0 (FIG. 20). This result suggests that after being in contact with a 0.8 mm region of the receiver substrate, most printable NWs on the donor have been printed and therefore, printing performance cannot be maintained beyond this point. SEM analysis was also carried out on the donor substrate following printing. The obtained images show that the contact width is around 0.85-0.9 mm (FIG. 20). This agrees with the contact width observed in the no rotation study. In addition, it can be derived that the “printing capacity” of the donor substrate is very close to unity, meaning that a given area on the donor is only able to sustain a similar area on the receiver substrate before printing performance degrades significantly.

Studying the alignment plot, reveals another aspect of the no sliding printing paradigm. The NW alignment is significantly lesser, reaching typical values only after the 0.75 mm point (FIG. 18A, upper righthand plot). Alignment remains within the typical range during the decrease of NW density. This could be attributed to the no sliding paradigm resulting in a receiver region with minimal interaction with the donor at the beginning of the process. A comparison with the results obtained during the no rotation study further supports the premise of the interactions between donor and receiver NWs affecting the NW alignment.

The velocity ratio variation paradigm enables control over the donor and receiver areas with an end goal to fine tune the printing performance. The areas of the donor and receiver that are in contact during printing, are directly proportional to the velocities of the horizontal and rotation platforms. By varying the ratio of the two velocities, different area ratios can be achieved, steering away from the 1:1 ratio that is permissible with the conventional planar contact printing approach. Enabling this paradigm was one of the main motivations for perusing a roll-based contact printing approach. Using the developed setup and by varying the velocities of the independently moving platforms, density-oriented and area-oriented printing can be achieved. For these experiments, two density-oriented and two area-oriented ratios were tested for the values for horizontal and rotation velocities shown in the Table 1. A 1:1 ratio sample is also included in these studies. Importantly, while the ratio of the platform velocities varies, the differential velocity is kept constant at 0.1 mm/s to be consistent with previous experiments. Like previous studies, the applied force was set to 0.8 N. The horizontal displacement was set to 10 mm for all experiments; however, this parameter is not expected to affect the printing performance if it is set higher than the minimum contact width.

Upon inspecting the results of the SEM image analysis, the findings do follow the trends observed during the no rotation and no sliding studies. This is expected since these two paradigms are closely related to the velocity ratio variation paradigm.

TABLE 1
Velocity ratio variation study parameters.

| | Horizontal | Rotation | Differential | Ratio |
|---|---|---|---|---|
| | velocity | velocity | velocity | (Receiver/ |
| | (mm/s) | (mm/s) | (mm/s) | Donor) |
| Density- | 0.0835 | 0.0165 | 0.1 | 0.198 |
| oriented | 0.075 | 0.025 | 0.1 | 0.333 |
| Unity ratio | 0.05 | 0.05 | 0.1 | 1 |
| Area-oriented | 0.04 | 0.06 | 0.1 | 1.5 |
| | 0.025 | 0.075 | 0.1 | 3 |

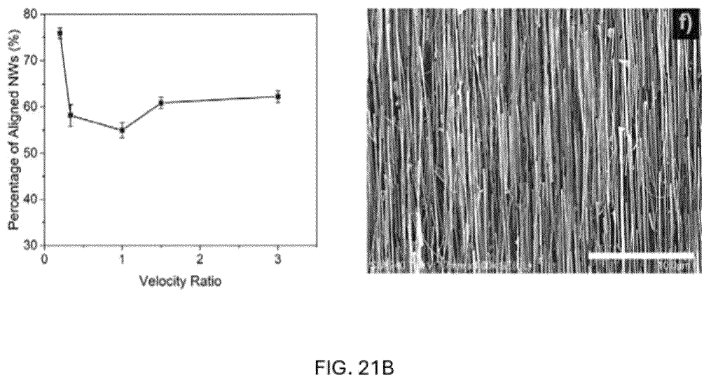

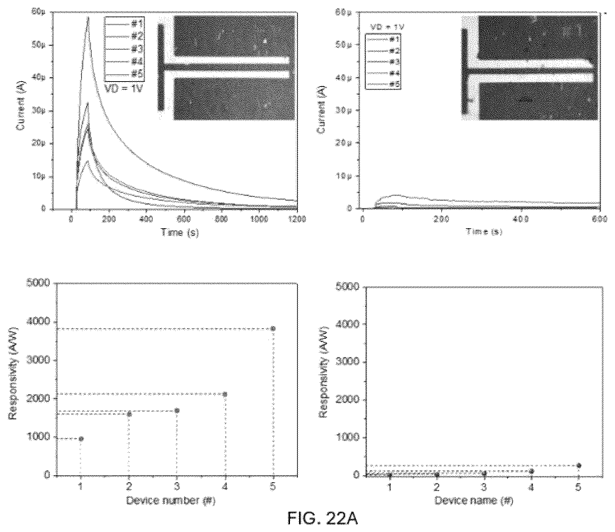

For the density-oriented experiments (ratio <1) the length density increases compared to the unity ratio case (FIG. 21A, 21B). At the lowest ratio of 0.2, the density reaches around 6.5 NW/μm. Inversely, for the area-oriented studies (ratio >1) density decreases dropping to around 1.2 NW/μm at the highest ratio (3). Area coverage follows the same trend, reaching over 45% for the higher density sample, while dropping to 6% for the least dense sample (FIG. 21A). The variation coefficients of these two figures of merit demonstrate that the uniformity of the printed layers significantly improves for the higher density samples, while variation across the lower density samples is considerably larger (FIG. 21A). Regarding NW alignment, all samples demonstrate sufficient alignment, with the lowest ratio sample showing a slight improvement (FIG. 21B). The density-oriented experiments, like the no rotation experiments, could be considered to operate within a “saturation regime.” As the number of NWs available to be printed per area increases, the density of the printed layer increases and any variations across the printed area become less significant. This could be attributed in part to the increased interactions between donor and receiver NWs. In the case of the area-oriented experiments, the number of NWs available to be printed per area is reduced. As observed during the no sliding studies, the “printing capacity” of the donor substrate greatly reduces beyond the unity ratio point. In the cases of larger than unity ratio, this can result in variation across the printing area, which is amplified as the ratio increases. In addition, the fewer interactions between NWs have a reduced impact across the printed area. From this study, some optimal printing parameters can be extracted. Velocity ratios <1 can be selected to fine tune the required NW density and uniformity for a given application. For example, for a ratio around 0.3 the area coverage is doubled compared to the unity case, while the density variation is halved, suggesting a significant improvement in uniformity. On the other hand, velocity ratios within the 1-1.5 range can be used for applications where larger throughput is preferred, without drastically compromising density and uniformity.

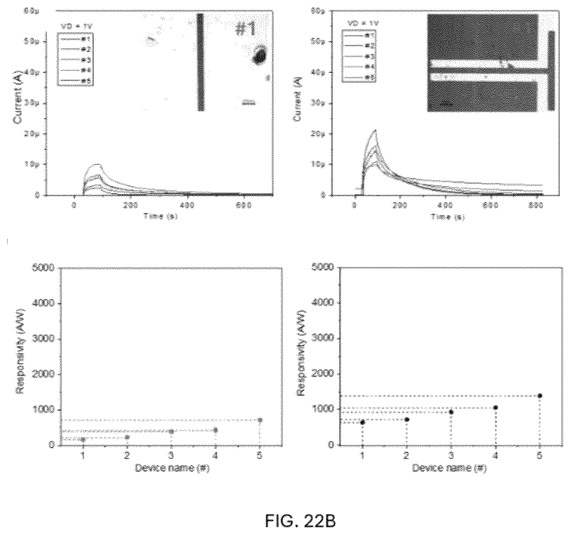

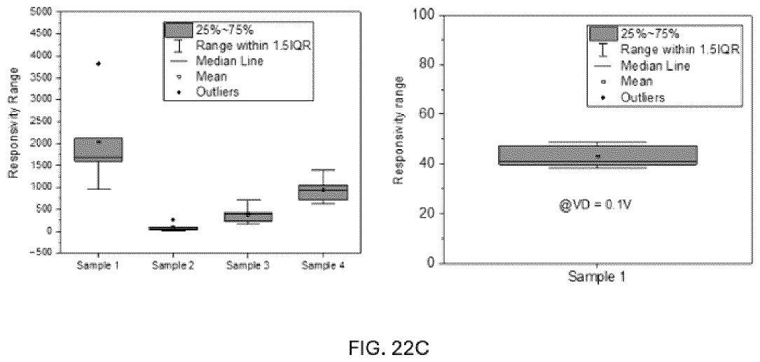

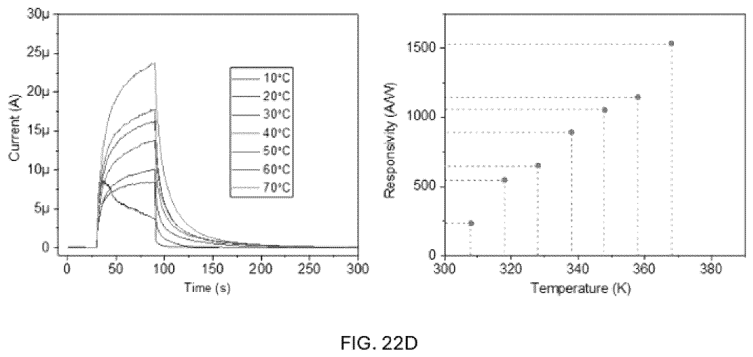

A well-aligned and densely packed NW-network plays a critical role in enhancing charge transport efficiency, leading to faster photo response and greater sensitivity in photo detectors (PDs). Higher NW density expands the active sensing area, resulting in increased UV light absorption and a higher number of photogenerated charge carriers, which collectively contribute to enhanced device responsivity. However, excessive NW density can lead to overlapping structures, causing increased charge scattering and degradation of device performance. A uniform NW alignment minimizes junction resistance and promotes directional charge transport, which is essential for achieving low-noise and fast photo detection. Despite the theoretical understanding, there is a lack of systematic experimental studies validating the influence of NW density on UV PD performance. Utilizing the unique capability of our roll-based printing system to precisely control NW density, we investigated the effect of NW density in the sensing channel on photodetector behavior. Four sets of samples with varying NW densities were fabricated by adjusting the horizontal displacement of the stage between 2 mm and 5 mm (with no rolling), resulting in linear NW densities of 2, 4, 6, and 8 NW/μm. Notably, the NW alignment in each of these samples is similar and near perfect. Each NW density sample included five devices, all tested under identical conditions. Single cycle photo response measurements were performed at a UV light intensity of 0.7 mW/cm² and a bias voltage of 1 V. The results are presented in FIG. 22A (upper left) (8 NW/μm), 5c (2 NW/μm), 5e (4 NW/μm), and 5g (6 NW/μm), with corresponding optical images inset. A clear trend of increasing light current with increasing NW density was observed. Responsivity values extracted from these measurements are plotted in FIG. 22A (lower left, lower right) and FIG. 22B (lower left and lower right). The highest responsivity (˜4000 A/W) was achieved from devices with the highest NW density (8 NW/μm). To assess device uniformity, a box-and-whisker plot (FIG. 22C, lefthand side) was used to visualize the distribution of responsivity across samples. Samples with NW densities of 4 NW/μm and 6 NW/μm (Samples 3 and 4) demonstrated the best uniformity. Although Sample 1 (8 NW/μm) showed the highest responsivity, one outlier was observed—likely due to localized NW overlap causing non-uniform behavior. Further measurements were carried out on Sample 1 at a reduced bias voltage of 0.1 V, where lower light currents resulted in decreased responsivity but improved uniformity across devices.

To examine thermal stability, photodetector performance was also evaluated at various temperatures (10-70° C.) under constant illumination (0.7 mW/cm²). The temperature-dependent photo response is shown in FIG. 5k, with corresponding responsivity values in FIG. 22D (right-hand side). A slight increase in both dark and photocurrents was observed with rising temperature. This is attributed to increased carrier kinetic energy, which enhances thermionic emission across the metal-semiconductor (MS) interface and boosts photogenerated current under illumination—thereby increasing responsivity.

The developed roll-based contact printing system printer 100 enabled the implementation and evaluation of printing paradigms which were not feasible with the planar contact printing setup. Through the various studies of these paradigms, a better overall understanding of the contact printing process was achieved. Further, the advantages of a roll-based approach were highlighted. Perhaps the most important advantage that was identified during these studies is the ability of the roll-based contact printing approach to decouple printing performance factors such as uniformity from the donor substrate's condition. This was one of the major shortcomings of the planar contact printing approach. The studies revealed that when printing under density-oriented conditions (ratio <1), the uniformity of the printed layer can be greatly improved through increase of the density, improvement of alignment and even removal of defects such as nanomembranes/nanostructures which can often be found across the donor. Velocity ratio variation during density-oriented printing provides an additional and more effective means for controlling the density of the printed layers. Previously, this could only be achieved via controlling the applied pressure which poses limitations for both the system's design and choice of substrates. Velocity ratio variation avoids such limitations, while being able to derive a wider range of densities. During the studies, a maximum density of over 14 NW/μm was achieved, which is 50% greater than what was previously achieved with any contact printing approach. In addition, a 2× improvement over the differential roll printing approach and 7× improvement over the dry planar contact printing approach was achieved. Importantly, the density-oriented printing has been made possible through the purposeful design of the roll-based setup and has not been possible with the previously reported approaches. Regarding the area-oriented conditions (ratio >1), the studies revealed that targeting large area increase might not be suitable for most applications, due to the negative impact on uniformity deriving from the donor's low “printing capacity”. However, when considering ratios at the lower end of the spectrum, between 1 and 1.5, drop in printing performance can be negligible compared to the unity ratio case, making this a viable option. The system's design allows for fine control over the ratio to dial in the optimal condition. In the context of large-scale fabrication, even a small increase in the velocity ratio could have a significant impact on production throughput.

While the disclosed subject matter is described herein in terms of certain preferred embodiments, those skilled in the art will recognize that various modifications and improvements may be made to the disclosed subject matter without departing from the scope thereof. Moreover, although individual features of one embodiment of the disclosed subject matter may be discussed herein or shown in the drawings of the one embodiment and not in other embodiments, it should be apparent that individual features of one embodiment may be combined with one or more features of another embodiment or features from a plurality of embodiments.

In addition to the specific embodiments claimed below, the disclosed subject matter is also directed to other embodiments having any other possible combination of the dependent features claimed below and those disclosed above. As such, the particular features presented in the dependent claims and disclosed above can be combined with each other in other manners within the scope of the disclosed subject matter such that the disclosed subject matter should be recognized as also specifically directed to other embodiments having any other possible combinations. Thus, the foregoing description of specific embodiments of the disclosed subject matter has been presented for purposes of illustration and description. It is not intended to be exhaustive or to limit the disclosed subject matter to those embodiments disclosed.

It will be apparent to those skilled in the art that various modifications and variations can be made in the method and system of the disclosed subject matter without departing from the spirit or scope of the disclosed subject matter. Thus, it is intended that the disclosed subject matter include modifications and variations that are within the scope of the appended claims and their equivalents.

What is claimed is:

1. A system for roll-based printing nanowires on a substrate, the system comprising:
a horizontal stage configured to translate along a first horizontal axis;
a goniometer stage coupled to the horizontal stage;
a donor substrate platform coupled to the goniometer stage;
a vertical stage configured to translate along a vertical axis; and
a receiver substrate platform having a cylindrical surface extending from a first end to a second end along a second horizontal axis, the second horizontal axis perpendicular to the first horizontal axis, the receiver substrate platform rotatably coupled to the vertical stage.

2. The system of claim 1, wherein the donor substrate platform comprises a first load cell and a second load cell spaced along the second horizontal axis.

3. The system of claim 1, wherein the goniometer stage is configured to rotate the donor substrate platform about the first horizontal axis.

4. The system of claim 3, wherein the goniometer stage comprises an actuator configured to automatedly rotate the goniometer about the first horizontal axis.

5. The system of claim 4, further comprising at least one controller in communication with the goniometer stage.

6. The system of claim 1, further comprising a first camera, the first camera oriented along the second horizontal axis and configured to capture at least one image of the donor substrate platform and the receiver substrate platform.

7. The system of claim 1, further comprising a second camera coupled to the vertical platform and configured to capture at least one image of the donor substrate platform relative to the first horizontal axis.

8. The system of claim 1, further comprising at least one actuator, the at least one actuator configured to translate at least one of the vertical stage and the horizontal stage.

9. The system of claim 8, further comprising at least one controller in communication with the at least one actuator configured to control a displacement of at least one of the vertical stage and horizontal stage.

10. The system of claim 1, wherein the horizontal stage is configured to translate along the second horizontal axis.

11. The system of claim 10, further comprising a rotating donor substrate stage configured to rotate the donor substrate platform about the vertical axis.

12. The system of claim 11, further comprising at least one actuator configured to automatedly translate the horizontal stage along the second horizontal axis and rotate the rotating donor substrate stage about the vertical axis.

13. The system of claim 1, wherein the donor substrate platform comprises a cylindrical loading surface oriented along the second horizontal axis.

14. The system of claim 1, wherein the donor substrate platform comprises at least one heating element.

15. The system of claim 1, wherein the donor substrate platform comprises a vacuum sample holder.

16. A method of roll-based printing of nanowires (NW) on a flexible substrate, the method comprising:
loading a donor substrate having a plurality of NW disposed thereon onto a donor substrate platform;
loading a receiver substrate on a receiver substrate platform;
aligning the donor substrate platform and the receiver substrate platform, wherein the aligning further comprises:
contacting the donor substrate platform with the receiver substrate platform;
detecting at least one force exerted by the receiver substrate platform on the donor substrate platform; and
moving at least one of the donor substrate platform and the receiver substrate platform, thereby printing at least a portion of the plurality of NW on the receiver substrate.

17. The method of claim 16, wherein aligning the donor substrate platform with the receiver substrate platform comprises rotating the donor substrate platform about a first horizontal axis.

18. The method of claim 16, wherein moving at least one of the donor substrate platform and the receiver substrate platform comprises translating the donor substrate platform along a first horizontal axis and rotating the receiver substrate platform about a second horizontal axis, simultaneously.

19. The method of claim 16, wherein moving at least one of the donor substrate platform and the receiver substrate platform comprises at least one of translating a vertical stage along a vertical axis and rotating the donor substrate platform about a first horizontal axis.

20. The method of claim 16, further comprising monitoring the printing of at least a portion of the plurality of NW on the receiver substrate platform
